(19) United States
(12) Patent Application Publication
(10) Pub. No.: US 2025/0356901 A1
(43) Pub. Date: Nov. 20, 2025

(54) DECISION FEEDBACK EQUALIZER SENSE AMPLIFIER CIRCUITS AND METHODS FOR DOUBLE DATA RATE NONVOLATILE MEMORY DEVICES

(71) Applicant: Sandisk Technologies, Inc., Milpitas, CA (US)

(72) Inventors: Jang Woo Lee, San Ramon, CA (US); Siddhesh Darne, Milpitas, CA (US); Venkatesh P. Ramachandra, San Jose, CA (US)

(73) Assignee: Sandisk Technologies, Inc., Milpitas, CA (US)

(21) Appl. No.: 18/663,824

(22) Filed: May 14, 2024

(51) Int. Cl. G11C 11/4076; G11C 11/4091; G11C 11/4096

(52) U.S. Cl. CPC G11C 11/4076; G11C 11/4091; G11C 11/4096

(57) ABSTRACT

An apparatus is provided that includes a first circuit stage that includes a current amplifier circuit configured to receive a data input signal and a feedback signal, and a second circuit stage including a voltage circuit coupled to the first circuit stage. The first circuit stage is configured to integrate a current based on the data input signal and the feedback signal. The second circuit stage is configured to provide an output signal corresponding to a decision of a value of the data input signal. The apparatus is configured to operate with a double data rate clocking scheme.

### BACKGROUND

Semiconductor memory is widely used in various electronic devices such as cellular telephones, digital cameras, personal digital assistants, medical electronics, mobile computing devices, servers, solid state drives, non-mobile computing devices and other devices. Semiconductor memory may be non-volatile memory or volatile memory. A non-volatile memory allows information to be stored and retained even when the non-volatile memory is not connected to a source of power (e.g., a battery).

Non-volatile memory devices include one or more memory chips having multiple arrays of memory cells. The memory arrays may have associated decoders and circuits for performing read, write, and erase operations. Memory cells within the arrays may be arranged in horizontal rows and vertical columns. Each row may be addressed by a word line, and each column may be addressed by a bit line. Data may be loaded into columns of the array using a series of data busses. Each column may hold a predefined unit of data, for instance, a word encompassing two bytes of information.

However, various challenges exist in fabricating such non-volatile memory devices.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIGS. 3A and 3B depict different embodiments of integrated memory assemblies.

FIG. 4A is a perspective view of a portion of one embodiment of a monolithic three dimensional memory structure.

FIG. 4B is a block diagram of one embodiment of a memory structure having four planes.

FIG. 4C depicts a top view of a portion of one embodiment of a block of memory cells.

FIG. 4D depicts a cross sectional view of a portion of one embodiment of a block of memory cells.

FIG. 4E depicts a cross sectional view of a portion of one embodiment of a block of memory cells.

FIG. 4F is a cross sectional view of one embodiment of a vertical column of memory cells.

FIG. 4G is a schematic of a plurality of NAND strings in multiple regions of a same block.

FIGS. 5A-5D are diagrams each depicting example threshold voltage distributions.

FIG. 6 is a simplified diagram depicting a memory controller interface 234 coupled via a data bus to a memory die.

FIG. 7A is a diagram of an embodiment of a decision feedback equalizer sense amplifier circuit.

FIG. 7B is a diagram that depicts various electrical signals of the decision feedback equalizer sense amplifier circuit of FIG. 7A.

FIG. 7C is a simplified block diagram of an embodiment of a decision feedback equalizer system that includes decision feedback equalizer sense amplifier circuits of FIG. 7A.

FIG. 7D is a diagram that depicts various electrical signals of the decision feedback equalizer system of FIG. 7C.

FIG. 7E is a diagram of another embodiment of a decision feedback equalizer sense amplifier circuit.

FIG. 8 is a flowchart of a method for use with the decision feedback equalizer sense amplifier circuit of FIG. 7E.

### DETAILED DESCRIPTION

Non-volatile memory devices typically include a memory controller coupled to a memory array. Data read from the memory array typically are communicated to the memory controller via a memory interface and a communication channel. In some instances, characteristics of the communication channel distort the data read from the memory array. On such type of distortion is referred to as intersymbol interference in which previously received data interferes with subsequently received data.

One technique to suppress or cancel intersymbol interference is to apply an equalization operation to the received data. For example, a decision feedback equalizer circuit may be used to suppress intersymbol interference. However, various challenges exist implementing a decision feedback equalizer circuit in a non-volatile memory device. In particular, feedback path delays may impair the operation of a decision feedback equalizer circuit.

This problem is particularly difficult for non-volatile memory devices that use a double data rate clock scheme. Technology is described for fast feedback decision feedback equalizer circuits that overcome feedback path delays and are compatible with double data rate non-volatile memory devices.

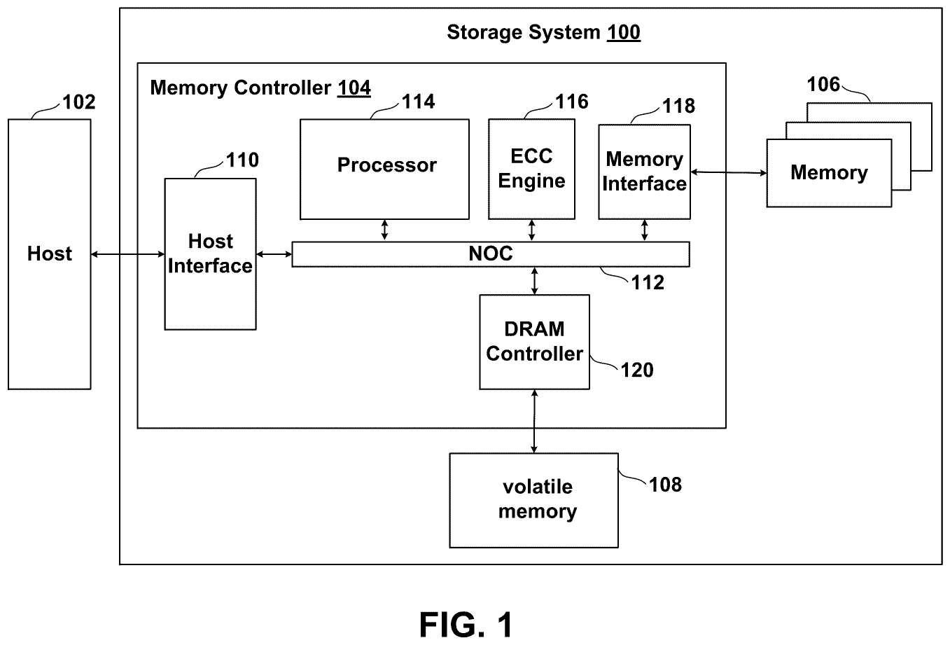

FIG. 1 is a block diagram of one embodiment of a storage system 100 that implements the proposed technology described herein. In one embodiment, storage system 100 is a solid state drive (“SSD”). Storage system 100 also can be a memory card, USB drive or other type of storage system. The proposed technology is not limited to any one type of memory system.

Storage system 100 is connected to a host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 104 connected to non-volatile memory 106 and local high speed volatile memory 108 (e.g., DRAM). Local high speed volatile memory 108 is used by memory controller 104 to perform certain functions. For example, local high speed volatile memory 108 stores logical to physical address translation tables (“L2P tables”).

Memory controller 104 includes a host interface 110 that is connected to and in communication with host 102. In one embodiment, host interface 110 implements a NVM Express (NVMe) over PCI Express (PCIe). Other interfaces can also be used, such as SCSI, SATA, etc. Host interface 110 also is connected to a network-on-chip (NOC) 112.

A NOC is a communication subsystem on an integrated circuit. NOC's can span synchronous and asynchronous clock domains or use un-clocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs.

The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 112 can be replaced by a bus.

Connected to and in communication with NOC 112 is a processor 114, an ECC engine 116, a memory interface 118, and a DRAM controller 120. DRAM controller 120 is used to operate and communicate with local high speed volatile memory 108 (e.g., DRAM). In other embodiments, local high speed volatile memory 108 can be SRAM or another type of volatile memory.

Processor 114 performs the various controller memory operations, such as programming, erasing, reading, and memory management processes. In one embodiment, processor 114 is programmed by firmware. In other embodiments, processor 114 is a custom and dedicated hardware circuit without any software. Processor 114 also implements a translation module, as a software/firmware process or as a dedicated hardware circuit.

In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 104 (e.g., the translation module) performs address translation between the logical addresses used by the host and the physical addresses used by the memory die.

One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables.

Instead, the logical address to physical address tables (or L2P tables) can be any type of data structure. In some examples, the memory space of a storage system is so large that the local memory 108 cannot hold all of the L2P tables. In such a case, the entire set of L2P tables are stored in non-volatile memory 106 and a subset of the L2P tables are cached (L2P cache) in the local high speed volatile memory 108.

ECC engine 116 performs error correction services. For example, ECC engine 116 performs data encoding and decoding, as per the implemented ECC technique. In one embodiment, ECC engine 116 is an electrical circuit programmed by software. For example, ECC engine 116 can be a processor that can be programmed. In other embodiments, ECC engine 116 is a custom and dedicated hardware circuit without any software. In another embodiment, the function of ECC engine 116 is implemented by processor 114.

Memory interface 118 communicates with non-volatile memory 106. In one embodiment, memory interface 118 provides a Toggle Mode interface. In another embodiment, memory interface 118 provides a double data rate (DDR) interface. Other interfaces also can be used. In some example implementations, memory interface 118 (or another portion of controller 104) implements a scheduler and buffer for transmitting data to and receiving data from one or more memory die.

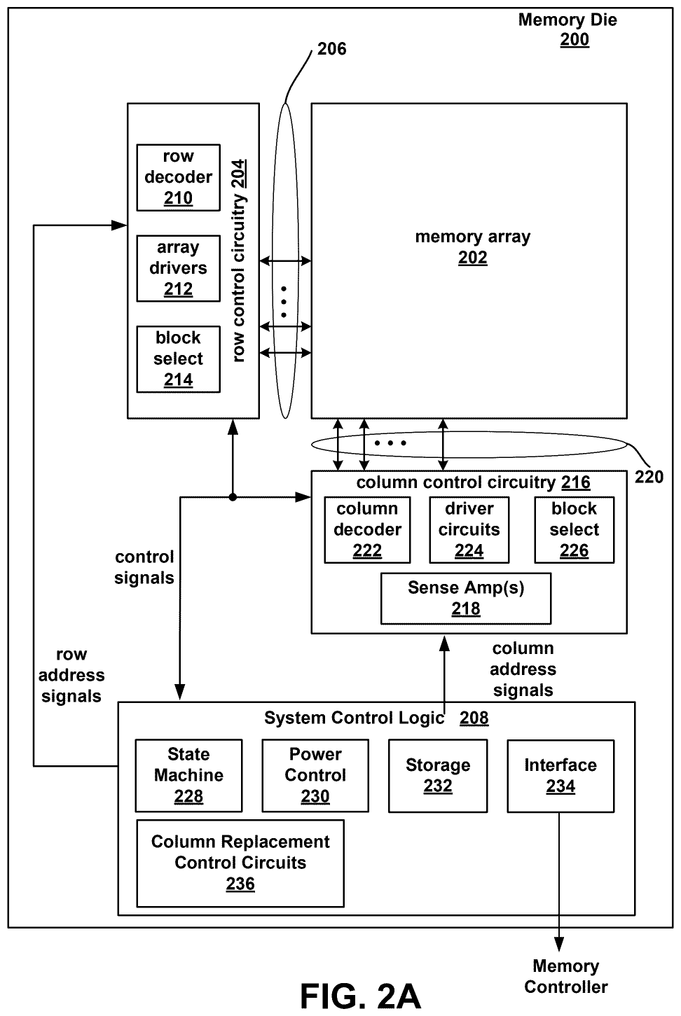

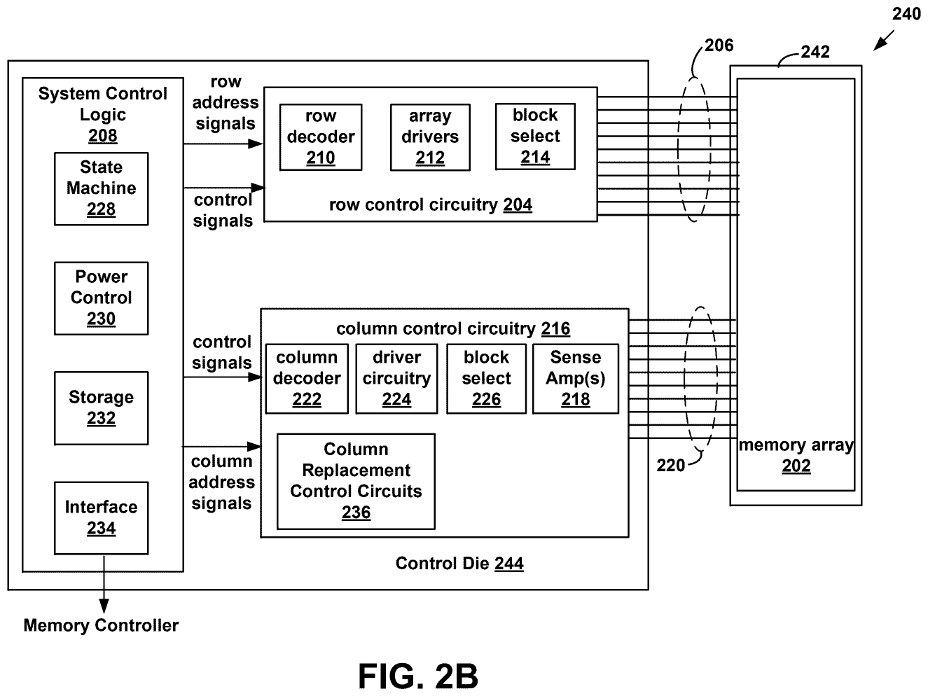

In one embodiment, non-volatile memory 106 includes one or more memory die. FIG. 2A is a functional block diagrams of one embodiment of a memory die 200 that includes non-volatile memory 106. Each of the one or more memory die of non-volatile memory 106 can be implemented as memory die 200 of FIG. 2A. The components depicted in FIG. 2A are electrical circuits.

Memory die 200 includes a memory array 202 that can include non-volatile memory cells, as described in more detail below. The array terminal lines of memory array 202 include the various layer(s) of word lines organized as rows, and the various layer(s) of bit lines organized as columns. However, other orientations can also be implemented.

Memory die 200 includes row control circuitry 204, whose outputs 206 are connected to respective word lines of the memory array 202. Row control circuitry 204 receives a group of M row address signals and one or more various control signals from system control logic circuit 208, and typically may include such circuits as row decoders 210, array terminal drivers 212, and block select circuitry 214 for both reading and writing (programming) operations.

Row control circuitry 204 also may include read/write circuitry. Memory die 200 also includes column control circuitry 216 including sense amplifier(s) 218 whose input/outputs 220 are connected to respective bit lines of memory array 202. Although only a single block is shown for memory array 202, a memory die can include multiple arrays that can be individually accessed.

Column control circuitry 216 receives a group of N column address signals and one or more various control signals from system control logic 208, and typically may include such circuits as column decoders 222, array terminal receivers or driver circuits 224, block select circuitry 226, as well as read/write circuitry, and I/O multiplexers.

System control logic 208 receives data and commands from memory controller 104 (FIG. 1) and provides output data and status to host 102. In some embodiments, system control logic 208 (which includes one or more electrical circuits) includes a state machine 228 that provides die-level control of memory operations.

In one embodiment, state machine 228 is programmable by software. In other embodiments, state machine 228 does not use software and is completely implemented in hardware (e.g., electrical circuits). In another embodiment, state machine 228 is replaced by a micro-controller or microprocessor, either on or off the memory chip.

System control logic 208 also can include a power control module 230 that controls the power and voltages supplied to the rows and columns of memory structure 202 during memory operations and may include charge pumps and regulator circuit for creating regulating voltages. System control logic 208 includes storage 232 (e.g., RAM, registers, latches, etc.), which may be used to store parameters for operating memory array 202.

Commands and data are transferred between memory controller 104 and memory die 200 via memory controller interface 234 (also referred to as a “communication interface”). Memory controller interface 234 is an electrical interface for communicating with memory controller 104. Examples of memory controller interface 234 include a Toggle Mode Interface, a DDR interface and an Open NAND Flash Interface (ONFI). Other I/O interfaces can also be used. In a DDR clock scheme, rising edges and falling edges of a clock signal are sampling transitions.

In an embodiment, system control logic 208 also includes column replacement control circuits 236, described in more detail below.

In some embodiments, all elements of memory die 200, including the system control logic 208, can be formed as part of a single die. In other embodiments, some or all of the system control logic 208 can be formed on a different die.

In one embodiment, memory structure 202 comprises a three-dimensional memory array of non-volatile memory cells in which multiple memory levels are formed above a single substrate, such as a wafer. Memory structure 202 may include any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 includes a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein.

Other examples of suitable technologies for memory cells of memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell.

A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells.

In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb₂Te₃ super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light.

In other PCM embodiments, the memory cells are programmed by current pulses. Note that the use of “pulse” in this document does not require a square pulse but includes a (continuous or non-continuous) vibration or burst of sound, current, voltage light, or another wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to memory structure 202. However, this reduces the area of the memory die available for the peripheral circuitry. This can place quite severe restrictions on these elements of the peripheral circuitry.

For example, the need to fit sense amplifier circuits within the available area can be a significant restriction on sense amplifier design architectures. With respect to system control logic 208, reduced availability of area can limit the available functions that can be implemented on-chip. Consequently, a basic trade-off in the design of a memory die for the storage system 100 is the amount of area to devote to memory structure 202 and the amount of area to devote to the peripheral circuitry.

Another area in which memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based.

For example, elements such sense amplifier circuits, charge pumps, logic elements in a state machine, and other peripheral circuitry in system control logic 208 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 2A onto separately formed die that are then bonded together. More specifically, memory structure 202 can be formed on one die (referred to as the memory die) and some or all of the peripheral circuitry elements, including one or more control circuits, can be formed on a separate die (referred to as the control die).

For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology.

For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array.

The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 240. One or more integrated memory assemblies 240 may be used to implement the non-volatile memory 106 of storage system 100.

Integrated memory assembly 240 includes two types of semiconductor die (or more succinctly, “die”). Memory die 242 includes memory structure 202. Memory structure 202 includes non-volatile memory cells. Control die 244 includes control circuitry 208, 216, and 204 (as described above). In some embodiments, control die 244 is configured to connect to memory structure 202 in memory die 242. In some embodiments, memory die 242 and control die 244 are bonded together.

FIG. 2B shows an example of the peripheral circuitry, including control circuits, formed in a peripheral circuit or control die 244 coupled to memory structure 202 formed in memory die 242. Common components are labelled similarly to FIG. 2A. System control logic 208, row control circuitry 204, and column control circuitry 216 are located in control die 244. In some embodiments, all or a portion of column control circuitry 216 and all or a portion of row control circuitry 204 are located on memory die 242. In some embodiments, some of the circuitry in system control logic 208 is located on memory die 242.

System control logic 208, row control circuitry 204, and column control circuitry 216 may be formed by a common process (e.g., CMOS process), so that adding elements and functions, such as ECC, more typically found on a memory controller 104 may require few or no additional process steps (i.e., the same process steps used to fabricate controller 104 may also be used to fabricate system control logic 208, row control circuitry 204, and column control circuitry 216).

Thus, while moving such circuits from a die such as memory 242 may reduce the number of steps needed to fabricate such a die, adding such circuits to a die such as control die 244 may not require many additional process steps. Control die 244 also could be referred to as a CMOS die, due to the use of CMOS technology to implement some or all of control circuitry 204, 208, 216.

FIG. 2B shows column control circuitry 216 including sense amplifier(s) 218 on control die 244 coupled to memory structure 202 on memory die 242 through electrical paths 220. For example, electrical paths 220 may provide electrical connection between column decoder 222, driver circuitry 224, and block select 226 and bit lines of memory structure 202. In an embodiment, column control circuitry 216 also includes column replacement control circuits 236, described in more detail below.

Electrical paths may extend from column control circuitry 216 in control die 244 through pads on control die 244 that are bonded to corresponding pads of the memory die 242, which are connected to bit lines of memory structure 202. Each bit line of memory structure 202 may have a corresponding electrical path in electrical paths 220, including a pair of bond pads, which connects to column control circuitry 216.

Similarly, row control circuitry 204, including row decoder 210, array drivers 212, and block select 214 are coupled to memory structure 202 through electrical paths 206. Each of electrical path 206 may correspond to a word line, dummy word line, or select gate line. Additional electrical paths may also be provided between control die 244 and memory die 242.

For purposes of this document, the phrases “a control circuit” or “one or more control circuits” can include any one of or any combination of memory controller 104, state machine 228, all or a portion of system control logic 208, all or a portion of row control circuitry 204, all or a portion of column control circuitry 216, a microcontroller, a microprocessor, and/or other similar functioned circuits.

The control circuit can include hardware only or a combination of hardware and software (including firmware). For example, a controller programmed by firmware to perform the functions described herein is one example of a control circuit. A control circuit can include a processor, FGA, ASIC, integrated circuit, or other type of circuit.

In some embodiments, there is more than one control die 244 and more than one memory die 242 in an integrated memory assembly 240. In some embodiments, the integrated memory assembly 240 includes a stack of multiple control die 244 and multiple memory die 242.

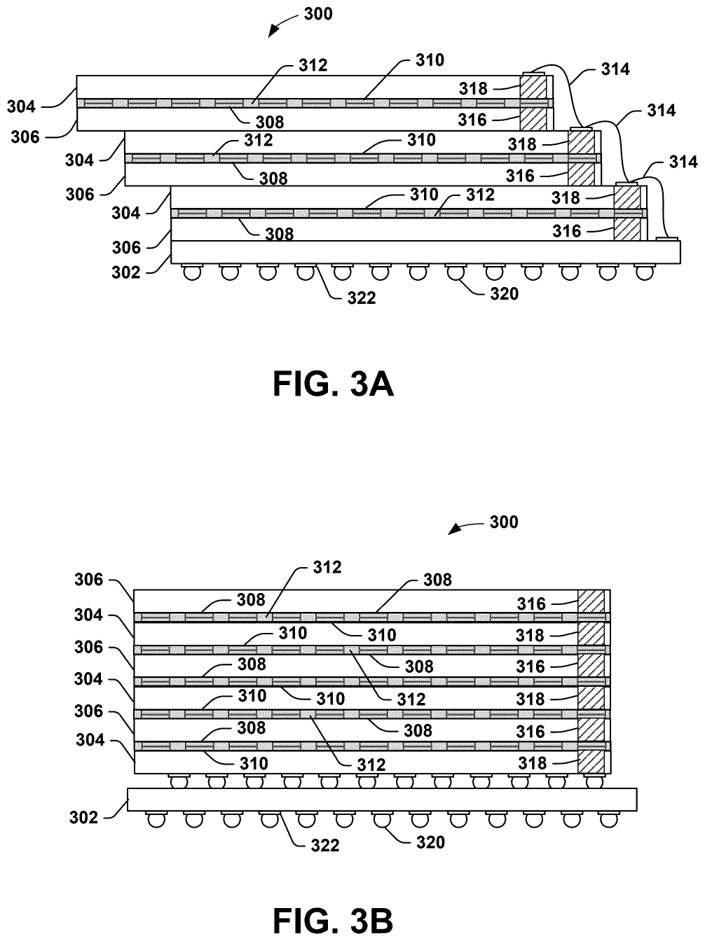

FIG. 3A depicts a side view of an embodiment of an integrated memory assembly 300 stacked on a substrate 302 (e.g., a stack including control die 304 and memory die 306). The integrated memory assembly 300 has three control die 304 and three memory die 306. In some embodiments, there are more than three memory die 306 and more than three control die 304.

Each control die 304 is affixed (e.g., bonded) to at least one memory die 306. Some of the bond pads 308/310 are depicted, although there may be many more bond pads. A space between two die 306, 304 that are bonded together is filled with a solid layer 312, which may be formed from epoxy or other resin or polymer. This solid layer 312 protects the electrical connections between the die 306, 304, and further secures the die together. Various materials may be used as solid layer 312, but in embodiments, it may be Hysol epoxy resin from Henkel Corp., having offices in California, USA.

Integrated memory assembly 300 may for example be stacked with a stepped offset, leaving the bond pads at each level uncovered and accessible from above. Wire bonds 314 connected to the bond pads connect control die 304 to substrate 302. A number of such wire bonds may be formed across the width of each control die 304 (i.e., into the page of FIG. 3A).

A memory die through silicon via (TSV) 316 may be used to route signals through each memory die 306. A control die TSV 318 may be used to route signals through each control die 304. The TSVs 316, 318 may be formed before, during or after formation of the integrated circuits in semiconductor die 306, 304. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 320 optionally may be affixed to contact pads 322 on a lower surface of substrate 302. Solder balls 320 may be used to couple integrated memory assembly 300 electrically and mechanically to a host device such as a printed circuit board. Solder balls 320 may be omitted where the integrated memory assembly 300 is to be used as an LGA package. Solder balls 320 may form a part of an interface between integrated memory assembly 300 and memory controller 104 (FIG. 1).

FIG. 3B depicts a side view of another embodiment of an integrated memory assembly 300 stacked on a substrate 302. The integrated memory assembly 300 of FIG. 3B has three control die 304 and three memory die 306. In some embodiments, there are many more than three memory die 306 and many more than three control die 304. In this example, each control die 304 is bonded to at least one memory die 306. Optionally, a control die 304 may be bonded to two or more memory die 306.

Some of the bond pads 308, 310 are depicted. There may be many more bond pads. A space between two die 306, 304 that are bonded together is filled with a solid layer 312, which may be formed from epoxy or other resin or polymer. In contrast to the example in FIG. 3A, integrated memory assembly 300 of FIG. 3B does not have a stepped offset. A memory die TSV 316 may be used to route signals through each memory die 306. A control die TSV 318 may be used to route signals through each control die 304.

As has been briefly discussed above, control die 304 and memory die 306 may be bonded together. Bond pads on each control die 304 and each memory die 306 may be used to bond the two die together. In some embodiments, the bond pads are bonded directly to each other, without solder or other added material, in a so-called Cu-to-Cu bonding process.

In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension.

Such bonds may be formed at room temperature, though heat also may be applied. In embodiments using cu-to-cu bonding, the bond pads may be about 5 μm square and spaced from each other with a pitch of 5 μm to 5 μm. Although this process is referred to herein as cu-to-cu bonding, this term also may apply even where the bond pads are formed of materials other than copper.

When the area of bond pads is small, it may be difficult to bond the semiconductor die together. The size of and pitch between bond pads may be further reduced by providing a film layer on the surfaces of the semiconductor die including the bond pads. The film layer is provided around the bond pads. When the die are brought together, the bond pads may bond to each other, and the film layers on the respective die may bond to each other.

Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller (or greater) sizes and pitches.

Some embodiments may include a film on surface of control die 304 and memory die 306. Where no such film is initially provided, a space between the die may be under filled with an epoxy or other resin or polymer. The under-fill material may be applied as a liquid which then hardens into a solid layer. This under-fill step protects the electrical connections between control die 304 and memory die 306, and further secures the die together. Various materials may be used as under-fill material, such as Hysol epoxy resin from Henkel Corp., having offices in California, USA.

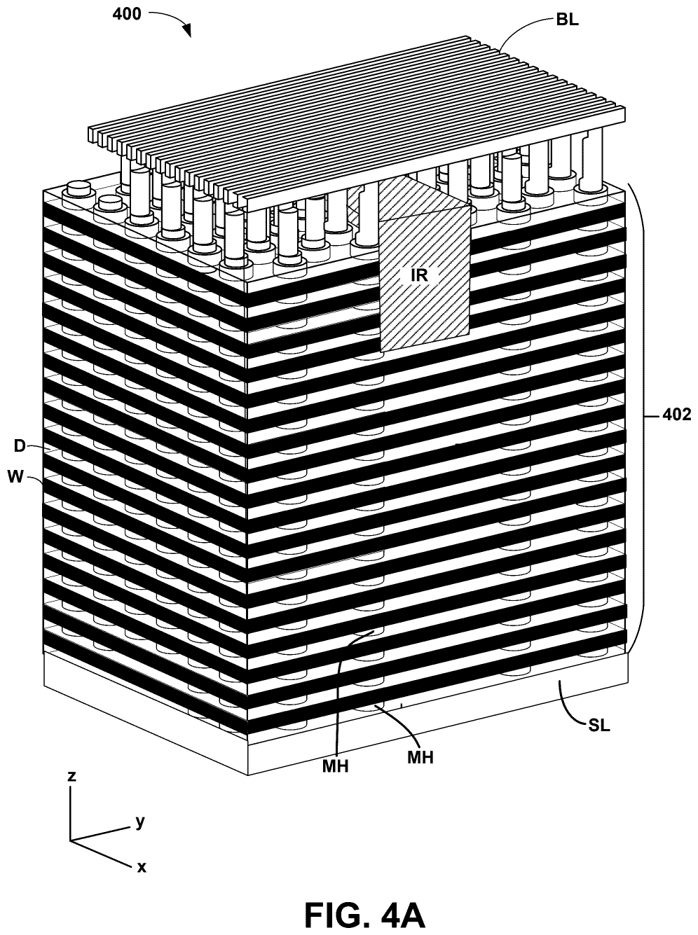

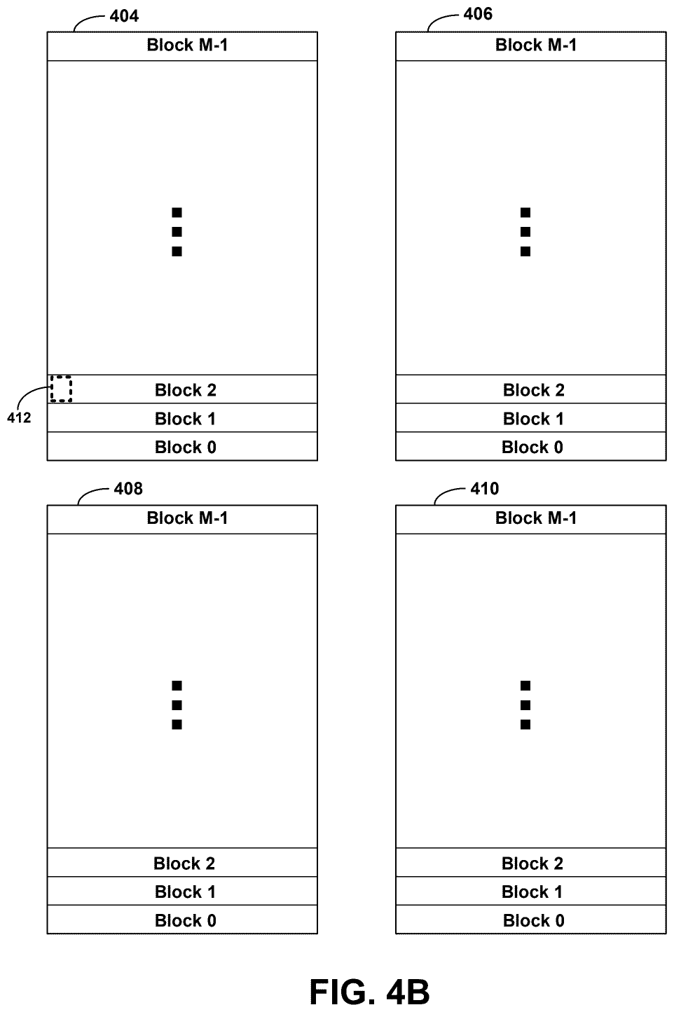

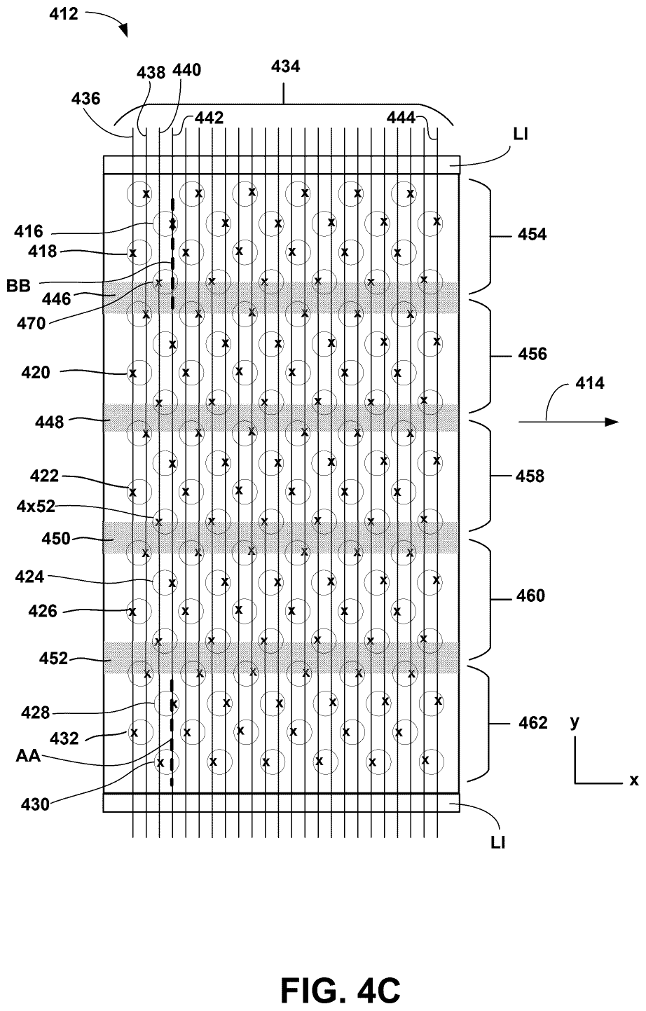

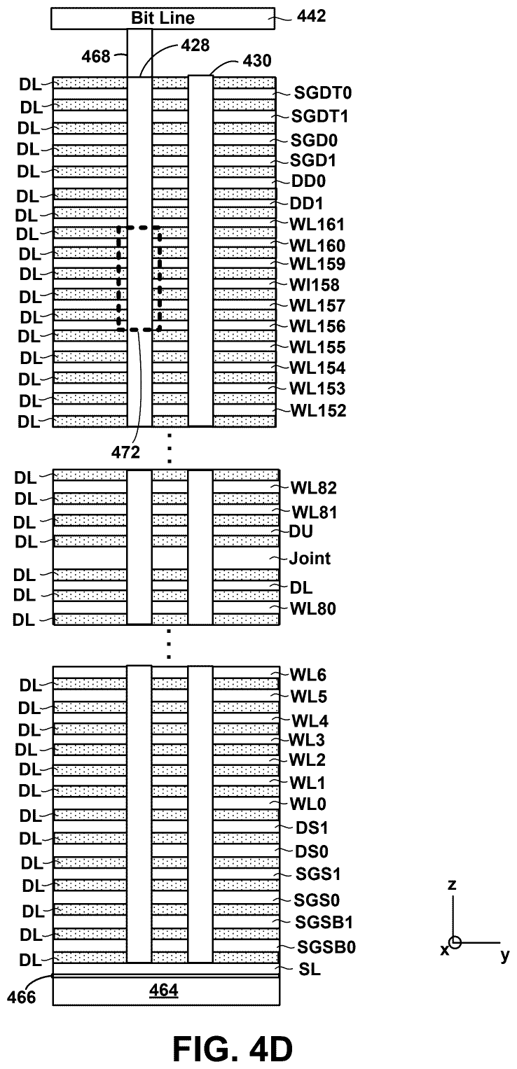

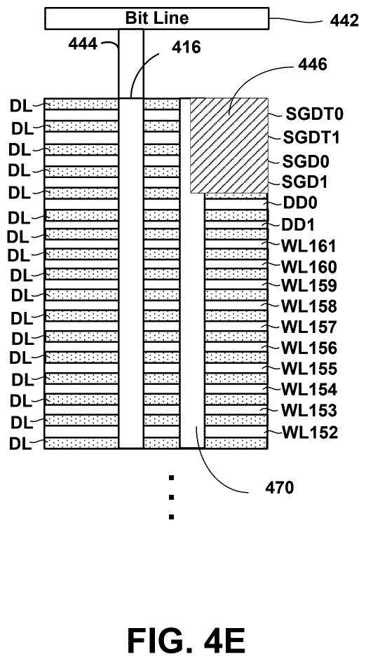

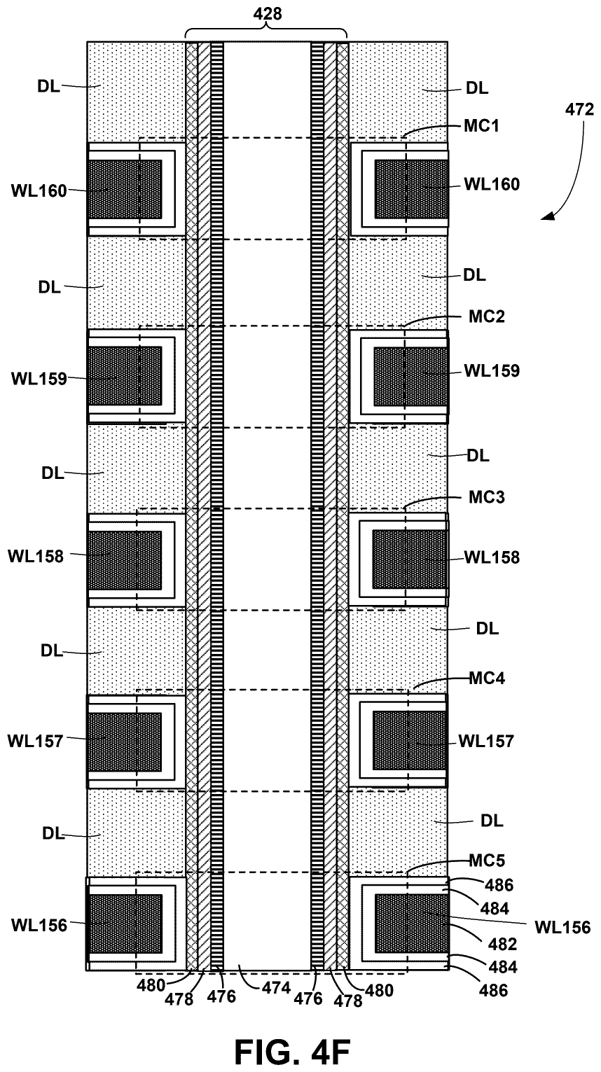

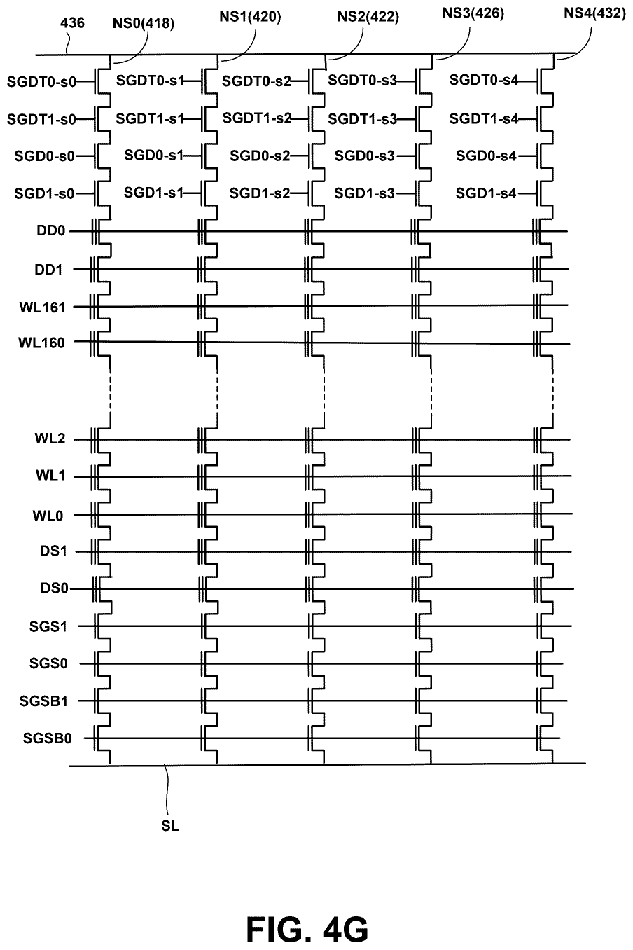

FIG. 4A is a perspective view of a portion of one example embodiment of a monolithic three dimensional memory array/structure included in memory structure 202, which includes a plurality non-volatile memory cells arranged as vertical NAND strings. For example, FIG. 4A shows a portion 400 of one block of memory.

The structure depicted includes a set of bit lines BL positioned above a stack 402 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements.

As will be explained below, in one embodiment the alternating dielectric layers and conductive layers are divided into four or five (or a different number of) regions by isolation regions IR. FIG. 4A shows one isolation region IR separating two regions. Below the alternating dielectric layers and word line layers is a source line layer SL. Memory holes are formed in the stack of alternating dielectric layers and conductive layers.

For example, one of the memory holes is marked as MH. Note that in FIG. 4A, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells.

Each memory cell can store one or more bits of data. Thus, the non-volatile memory cells are arranged in memory holes. More details of the three dimensional monolithic memory array that comprises memory structure 202 is provided below.

FIG. 4B is a block diagram explaining one example organization of memory structure 202, which is divided into four planes 404, 406, 408 and 410. Each plane is then divided into M blocks. In one example, each plane has about 2000 blocks. However, different numbers of blocks and planes can also be used.

In one embodiment, a block of memory cells is a unit of erase. That is, all memory cells of a block are erased together. In other embodiments, blocks can be divided into sub-blocks and the sub-blocks can be the unit of erase. Memory cells also can be grouped into blocks for other reasons, such as to organize the memory structure to enable the signaling and selection circuits.

In some embodiments, a block represents a groups of connected memory cells as the memory cells of a block share a common set of word lines. For example, the word lines for a block are all connected to all of the vertical NAND strings for that block. Although FIG. 4B shows four planes, more or less than four planes can be implemented. In some embodiments, memory structure 202 includes eight planes.

Each block typically is divided into one or more pages. In an embodiment, a page is a unit of programming/writing and a unit of reading. Other units of programming also can be used. In an embodiment, one or more pages of data are typically stored in one row of memory cells. For example, one or more pages of data may be stored in memory cells connected to a common word line. In an embodiment, a page includes data stored in all memory cells connected to a common word line.

FIGS. 4C-4G depict an example three dimensional (“3D”) NAND structure that corresponds to the structure of FIG. 4A and can be used to implement memory structure 202 of FIGS. 2A and 2B. FIG. 4C is a block diagram depicting a top view of a portion 412 of Block 2 of plane 404. As can be seen from FIG. 4C, the block depicted in FIG. 4C extends in the direction of 414. In one embodiment, the memory array has many layers. However, FIG. 4C only shows the top layer.

FIG. 4C depicts a plurality of circles that represent the memory holes, which are also referred to as vertical columns. Each of the memory holes/vertical columns include multiple select transistors (also referred to as a select gate or selection gate) and multiple memory cells. In one embodiment, each memory hole/vertical column implements a NAND string. For example, FIG. 4C labels a subset of the memory holes/vertical columns/NAND strings 416, 418, 420. 422, 424, 426, 428, 430 and 432.

FIG. 4C also depicts a set of bit lines 434, including bit lines 436, 438, 440, 442, . . . 444. FIG. 4C shows twenty four bit lines because only a portion of the block is depicted. It is contemplated that more than twenty four bit lines connected to memory holes/vertical columns of the block. Each of the circles representing memory holes/vertical columns has an “x” to indicate its connection to one bit line. For example, bit line 436 is connected to memory holes/vertical columns 418, 420, 422, 426 and 432.

The block depicted in FIG. 4C includes a set of isolation regions 446, 448, 450 and 452, which are formed of SiO₂. However, other dielectric materials also can be used. Isolation regions 446, 448, 450 and 452 serve to divide the top layers of the block into five regions For example, the top layer depicted in FIG. 4C is divided into regions 454, 456, 458, 460 and 462.

In one embodiment, the isolation regions only divide the layers used to implement select gates so that NAND strings in different regions can be independently selected. In one example implementation, a bit line connects to one memory hole/vertical column/NAND string in each of regions 454, 456, 458, 460 and 462. In that implementation, each block has twenty four rows of active columns and each bit line connects to five rows in each block.

In one embodiment, all of the five memory holes/vertical columns/NAND strings connected to a common bit line are connected to the same set of word lines; therefore, the system uses the drain side selection lines to choose one (or another subset) of the five to be subjected to a memory operation (program, verify, read, and/or erase).

FIG. 4C also shows Line Interconnects LI, which are metal connections to the source line SL from above the memory array. Line Interconnects LI are positioned adjacent regions 454 and 462.

Although FIG. 4C shows each region 454, 456, 458, 460 and 462 having four rows of memory holes/vertical columns, five regions and twenty four rows of memory holes/vertical columns in a block, those exact numbers are an example implementation. Other embodiments may include more or less regions per block, more or less rows of memory holes/vertical columns per region and more or less rows of vertical columns per block.

FIG. 4C also shows the memory holes/vertical columns being staggered. In other embodiments, different patterns of staggering can be used. In some embodiments, the memory holes/vertical columns are not staggered.

FIG. 4D depicts a portion of one embodiment of a three dimensional memory structure 202 showing a cross-sectional view along line AA of FIG. 4C. This cross sectional view cuts through memory holes/vertical columns (NAND strings) 428 and 430 of region 462 (see FIG. 4C).

The structure of FIG. 4D includes two drain side select layers SGD0 and SGD, the source side select layers SGS0 and SGS1, two drain side GIDL generation transistor layers SGDT0 and SGDT1, two source side GIDL generation transistor layers SGSB0 and SGSB1, two drain side dummy word line layers DD0 and DD1, two source side dummy word line layers DS0 and DS1, dummy word line layers DU and DL, one hundred and sixty two word line layers WL0-WL161 for connecting to data memory cells, and dielectric layers DL.

Other embodiments can implement more or less than the numbers described above for FIG. 4D. In one embodiment, SGD0 and SGD1 are connected together; and SGS0 and SGS1 are connected together. In other embodiments, more or less number of SGDs (greater or lesser than two) are connected together, and more or less number of SGS devices (greater or lesser than two) connected together.

In one embodiment, erasing the memory cells is performed using gate induced drain leakage (GIDL), which includes generating charge carriers at the GIDL generation transistors such that the carriers get injected into the charge trapping layers of the NAND strings to change threshold voltage of the memory cells. FIG. 4D shows two GIDL generation transistors at each end of the NAND string; however, in other embodiments there are more or less than three.

Embodiments that use GIDL at both sides of the NAND string may have GIDL generation transistors at both sides. Embodiments that use GIDL at only the drain side of the NAND string may have GIDL generation transistors only at the drain side. Embodiments that use GIDL at only the source side of the NAND string may have GIDL generation transistors only at the source side.

FIG. 4D shows two GIDL generation transistors at each end of the NAND string. It is likely that charge carriers are only generated by GIDL at one of the two GIDL generation transistors at each end of the NAND string. Based on process variances during manufacturing, it is likely that one of the two GIDL generation transistors at an end of the NAND string is best suited for GIDL.

For example, the GIDL generation transistors have an abrupt PN junction to generate the charge carriers for GIDL and, during fabrication, a phosphorous diffusion is performed at the polysilicon channel of the GIDL generation transistors. In some cases, the GIDL generation transistor with the shallowest phosphorous diffusion is the GIDL generation transistor that generates the charge carriers during erase. However, in some embodiments charge carriers can be generated by GIDL at multiple GIDL generation transistors at a particular side of the NAND string.

Memory holes/Vertical columns 428 and 430 are depicted protruding through the drain side select layers, source side select layers, dummy word line layers, GIDL generation transistor layers and word line layers. In one embodiment, each memory hole/vertical column comprises a vertical NAND string. Below the memory holes/vertical columns and the layers listed below is substrate 464, an insulating film 466 on the substrate, and source line SL. The NAND string of memory hole/vertical column 428 has a source end at a bottom of the stack and a drain end at a top of the stack. As in agreement with FIG. 4C, FIG. 4D show vertical memory hole/column 428 connected to bit line 442 via connector 468.

For ease of reference, drain side select layers, source side select layers, dummy word line layers, GIDL generation transistor layers and data word line layers collectively are referred to as conductive layers.

In one embodiment, the conductive layers are made from a combination of TiN and Tungsten. In other embodiments, other materials can be used to form the conductive layers, such as doped polysilicon, metal such as Tungsten, metal silicide, such as nickel silicide, tungsten silicide, aluminum silicide or the combination thereof.

In some embodiments, different conductive layers can be formed from different materials. Between conductive layers are dielectric layers DL. In one embodiment, the dielectric layers are made from SiO₂. In other embodiments, other dielectric materials can be used to form the dielectric layers.

The non-volatile memory cells are formed along memory holes/vertical columns which extend through alternating conductive and dielectric layers in the stack. In one embodiment, the memory cells are arranged in NAND strings. The word line layers WL0-W161 connect to memory cells (also called data memory cells). Dummy word line layers connect to dummy memory cells.

A dummy memory cell does not store and is not eligible to store host data (data provided from the host, such as data from a user of the host), while a data memory cell is eligible to store host data. In some embodiments, data memory cells and dummy memory cells may have a same structure. Drain side select layers SGD0 and SGD1 are used to electrically connect and disconnect NAND strings from bit lines. Source side select layers SGS0 and SGS1 are used to electrically connect and disconnect NAND strings from the source line SL.

FIG. 4D shows that the memory array is implemented as a two tier architecture, with the tiers separated by a Joint area. In one embodiment it is expensive and/or challenging to etch so many word line layers intermixed with dielectric layers. To ease this burden, one embodiment includes laying down a first stack of word line layers (e.g., WL0-WL80) alternating with dielectric layers, laying down the Joint area, and laying down a second stack of word line layers (e.g., WL81-WL161) alternating with dielectric layers. The Joint area are positioned between the first stack and the second stack. In one embodiment, the Joint areas are made from the same materials as the word line layers. In other embodiments, there can no Joint area or there can be multiple Joint areas.

FIG. 4E depicts a portion of one embodiment of a three dimensional memory structure 202 showing a cross-sectional view along line BB of FIG. 4C. This cross sectional view cuts through memory holes/vertical columns (NAND strings) 416 and 470 of region 454 (see FIG. 4C). FIG. 4E shows the same alternating conductive and dielectric layers as FIG. 4D.

FIG. 4E also shows isolation region 446. Isolation regions 446, 448, 450 and 452) occupy space that would have been used for a portion of the memory holes/vertical columns/NAND stings. For example, isolation region 446 occupies space that would have been used for a portion of memory hole/vertical column 470. More specifically, a portion (e.g., half the diameter) of vertical column 470 has been removed in layers SGDT0, SGDT1, SGD0, and SGD1 to accommodate isolation region 446.

Thus, while most of the vertical column 470 is cylindrical (with a circular cross section), the portion of vertical column 470 in layers SGDT0, SGDT1, SGD0, and SGD1 has a semi-circular cross section. In one embodiment, after the stack of alternating conductive and dielectric layers is formed, the stack is etched to create space for the isolation region and that space is then filled in with SiO₂. This structure allows for separate control of SGDT0, SGDT1, SGD0, and SGD1 for regions 454, 456, 458, 460, and 462.

FIG. 4F depicts a cross sectional view of region 472 of FIG. 4D that includes a portion of memory hole/vertical column 428. In one embodiment, the memory holes/vertical columns are round. However, in other embodiments other shapes can be used. In one embodiment, memory hole/vertical column 428 includes an inner core layer 474 that is made of a dielectric, such as SiO₂. Other materials can also be used.

Surrounding inner core 474 is polysilicon channel 476. Materials other than polysilicon can also be used. Note that it is the channel 476 that connects to the bit line and the source line. Surrounding channel 476 is a tunneling dielectric 478. In one embodiment, tunneling dielectric 478 has an ONO structure. Surrounding tunneling dielectric 478 is charge trapping layer 480, such as (for example) Silicon Nitride. Other memory materials and structures can also be used. The technology described herein is not limited to any particular material or structure.

FIG. 4F depicts dielectric layers DL as well as word line layers WL160, WL159, WL158, WL157, and WL156. Each of the word line layers includes a word line region 482 surrounded by an aluminum oxide layer 484, which is surrounded by a blocking oxide layer 486. In other embodiments, the blocking oxide layer can be a vertical layer parallel and adjacent to charge trapping layer 480. The physical interaction of the word line layers with the vertical column forms the memory cells.

Thus, in one embodiment a memory cell includes channel 476, tunneling dielectric 478, charge trapping layer 480, blocking oxide layer 486, aluminum oxide layer 484 and word line region 482. For example, word line layer WL160 and a portion of memory hole/vertical column 428 comprise a memory cell MC1. Word line layer WL159 and a portion of memory hole/vertical column 428 comprise a memory cell MC2. Word line layer WL158 and a portion of memory hole/vertical column 428 comprise a memory cell MC3. Word line layer WL157 and a portion of memory hole/vertical column 428 comprise a memory cell MC4. Word line layer WL156 and a portion of memory hole/vertical column 428 comprise a memory cell MC5. In other architectures, a memory cell may have a different structure; however, the memory cell would still be the storage unit.

When a memory cell is programmed, electrons are stored in a portion of the charge trapping layer 480 which is associated with (e.g. in) the memory cell. These electrons are drawn into the charge trapping layer 480 from the channel 476, through the tunneling dielectric 478, in response to an appropriate voltage on word line region 482. The threshold voltage (Vth) of a memory cell is increased in proportion to the amount of stored charge.

In one embodiment, the programming is achieved through Fowler-Nordheim tunneling of the electrons into the charge trapping layer. During an erase operation, the electrons return to the channel or holes are injected into the charge trapping layer to recombine with electrons. In one embodiment, erasing is achieved using hole injection into the charge trapping layer via a physical mechanism such as GIDL.

FIG. 4G is a schematic diagram of a portion of the three dimensional memory array 202 depicted in in FIGS. 4B-4F. FIG. 4G shows physical data word lines WL0-WL161 running across the entire block. The structure of FIG. 4G corresponds to a portion 412 in Block 2 of FIG. 4B, including bit line 436. Within the block, in one embodiment, each bit line is connected to five NAND strings, one in each region of regions 454, 456, 458, 460, 462.

Thus, FIG. 4G shows bit line 436 connected to NAND string NS0 (which corresponds to memory hole/vertical column 418 of region 454), NAND string NS1 (which corresponds to memory hole/vertical column 420 of region 456), NAND string NS2 (which corresponds to vertical column 422 of region 458), NAND string NS3 (which corresponds to memory hole/vertical column 426 of region 460), and NAND string NS4 (which corresponds to memory hole/vertical column 432 of region 462).

Drain side select line/layer SGD0 is separated by isolation regions isolation regions 446, 448, 450 and 452 to form SGD0-s0, SGD0-s1, SGD0-s2, SGD0-s3 and SGD0-s4 in order to separately connect to and independently control regions 454, 456, 458, 460, 462.

Similarly, drain side select line/layer SGD1 is separated by isolation regions 446, 448, 450 and 452 to form SGD1-s0, SGD1-s1, SGD1-s2, SGD1-s3 and SGD1-s4 in order to separately connect to and independently control regions 454, 456, 458, 460, 462.

Drain side GIDL generation transistor control line/layer SGDT0 is separated by isolation regions 446, 448, 450 and 452 to form SGDT0-s0, SGDT0-s1, SGDT0-s2, SGDT0-s3 and SGDT0-s4 in order to separately connect to and independently control regions 454, 456, 458, 460, 462.

Drain side GIDL generation transistor control line/layer SGDT1 is separated by isolation regions 446, 448, 450 and 452 to form SGDT1-s0, SGDT1-s1, SGDT1-s2, SGDT1-s3 and SGDT1-s4 in order to separately connect to and independently control regions 454, 456, 458, 460, 462.

FIG. 4G only shows NAND strings connected to bit line 436. However, a full schematic of the block would show every bit line and five vertical NAND strings (that are in separate regions) connected to each bit line.

Although the example memories of FIGS. 4B-4G are three dimensional memory structures that include vertical NAND strings with charge-trapping material, other (2D and 3D) memory structures can also be used with the technology described herein.

The memory systems discussed above can be erased, programmed and read. At the end of a successful programming process, the threshold voltages of the memory cells should be within one or more distributions of threshold voltages for programmed memory cells or within a distribution of threshold voltages for erased memory cells, as appropriate.

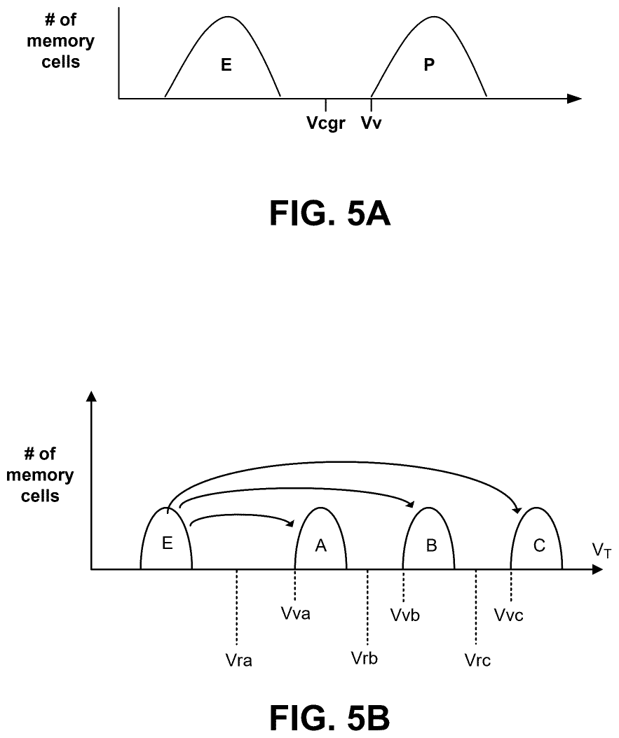

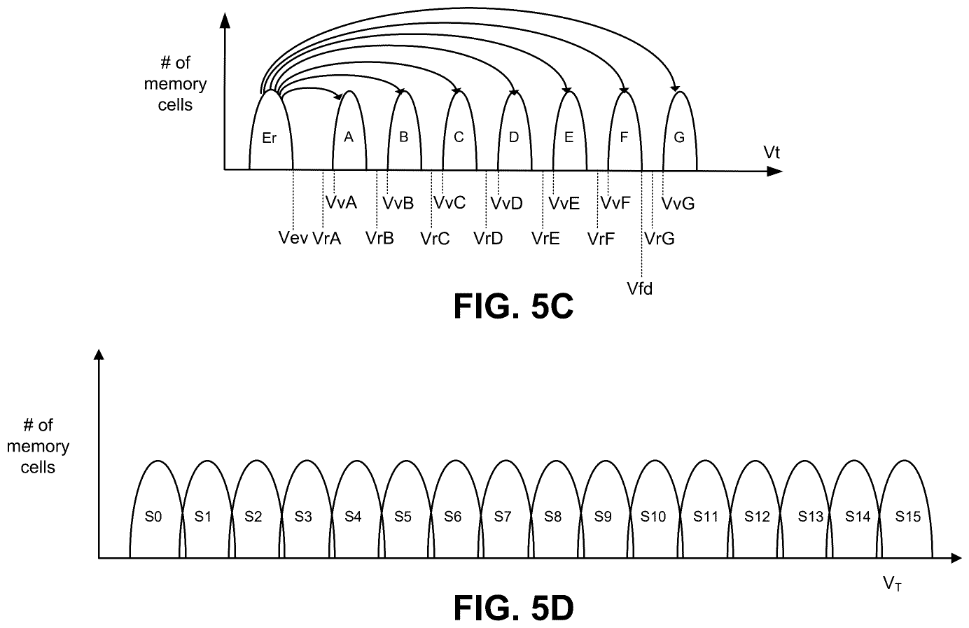

FIG. 5A is a diagram of example threshold voltage versus number of memory cells, and illustrates example threshold voltage distributions for the memory array when each memory cell stores one bit of data per memory cell. Memory cells that store one bit of data per memory cell data are referred to as single level cells (“SLC”).

FIG. 5A shows two threshold voltage distributions: E and P. Threshold voltage distribution E corresponds to an erased data state, and threshold voltage distribution P corresponds to a programmed data state. Memory cells that have threshold voltages in threshold voltage distribution E are in the erased data state. Memory cells that have threshold voltages in threshold voltage distribution P are in the programmed data state.

In one embodiment, erased memory cells store data “1” and programmed memory cells store data “0.” FIG. 5A depicts read reference voltage VCGR. By testing (e.g., performing one or more sense operations) whether the threshold voltage of a given memory cell is above or below VCGR, the system can determine whether a memory cells is erased (state E) or programmed (state P). FIG. 5A also depicts verify reference voltage Vv. In some embodiments, when programming memory cells to data state P, the system will test whether those memory cells have a threshold voltage greater than or equal to Vv.

In general, during read operations, a selected word line is connected to read reference voltage VCGR, and a conduction current of the memory cell is measured to determine whether the memory cell turned ON (conducted current) in response to the voltage applied to the word line. If the conduction current is measured to be greater than a certain value, then it is assumed that the memory cell turned ON and the threshold voltage of the memory cell is less than the voltage applied to the word line.

In contrast, if the conduction current is not measured to be greater than the certain value, then it is assumed that the memory cell did not turn ON and the threshold voltage of the memory cell is greater than the voltage applied to the word line. During a read process, unselected memory cells are provided with a read pass voltage VREAD (also referred to as a bypass voltage) at their control gates so that these memory cells will operate as pass gates (e.g., conducting current regardless of whether they are programmed or erased).

FIGS. 5B-D illustrate example threshold voltage distributions for a memory array in which each memory cell stores multiple bit per memory cell data. Memory cells that store multiple bit per memory cell data are referred to as multi-level cells (MLC). The data stored in MLC memory cells are referred to as MLC data. In the example embodiment of FIG. 5B, each memory cell stores two bits of data. Other embodiments may use other data capacities per memory cell (e.g., such as three, four, or five or more bits of data per memory cell).

FIG. 5B shows a first threshold voltage distribution E for erased memory cells. Three threshold voltage distributions A, B and C for programmed memory cells also are depicted. In one embodiment, the threshold voltages in the distribution E are negative and the threshold voltages in distributions A, B and C are positive. Each distinct threshold voltage distribution of FIG. 5B corresponds to predetermined values for the set of data bits.

In one embodiment, the two bits of data stored in a memory cell are in different logical pages, referred to as a lower page (LP) and an upper page (UP). In other embodiments, all bits of data stored in a memory cell are in a common logical page. The specific relationship between the data programmed into the memory cell and the threshold voltage levels of the cell depends upon the data encoding scheme adopted for the cells. Table 1 provides an example encoding scheme.

TABLE 1

| | E | A | B | C |
|---|---|---|---|---|
| LP | 1 | 0 | 0 | 1 |
| UP | 1 | 1 | 0 | 0 |

In one embodiment, known as full sequence programming, memory cells can be programmed from the erased data state E directly to any of the programmed data states A, B or C. For example, a population of memory cells to be programmed may first be erased so that all memory cells in the population are in erased data state E. Then, a programming process is used to program memory cells directly into data states A, B, and/or C.

For example, while some memory cells are being programmed from data state E to data state A, other memory cells are being programmed from data state E to data state B and/or from data state E to data state C. The arrows of FIG. 5B represent full sequence programming. In some embodiments, data states A-C can overlap, with memory controller 104 (or control die 244) relying on error correction to identify the correct data being stored.

FIG. 5C depicts example threshold voltage distributions for memory cells where each memory cell stores three bits of data per memory cells (which is another example of MLC data). FIG. 5C shows eight threshold voltage distributions, corresponding to eight data states. The first threshold voltage distribution (data state) Er represents memory cells that are erased. The other seven threshold voltage distributions (data states) A-G represent memory cells that are programmed and, therefore, also are called programmed states.

Each threshold voltage distribution (data state) corresponds to predetermined values for the set of data bits. The specific relationship between the data programmed into the memory cell and the threshold voltage levels of the cell depends upon the data encoding scheme adopted for the cells.

In one embodiment, data values are assigned to the threshold voltage ranges using a Gray code assignment so that if the threshold voltage of a memory erroneously shifts to its neighboring physical state, only one bit will be affected. Table 2 provides an example of an encoding scheme for embodiments in which each bit of data of the three bits of data stored in a memory cell are in different logical pages, referred to as a lower page (LP), middle page (MP) and an upper page (UP).

TABLE 2

| | Er | A | B | C | D | E | F | G |
|---|---|---|---|---|---|---|---|---|
| LP | 1 | 1 | 1 | 0 | 0 | 0 | 0 | 1 |
| MP | 1 | 1 | 0 | 0 | 1 | 1 | 0 | 0 |
| UP | 1 | 0 | 0 | 0 | 0 | 1 | 1 | 1 |

FIG. 5C shows seven read reference voltages, VrA, VrB, VrC, VrD, VrE, VrF, and VrG for reading data from memory cells. By testing (e.g., performing sense operations) whether the threshold voltage of a given memory cell is above or below the seven read reference voltages, the system can determine what data state (e.g., A, B, C, D, . . . ) a memory cell is in.

FIG. 5C also shows seven verify reference voltages, VvA, VvB, VvC, VvD, VvE, VvF, and VvG. In some embodiments, when programming memory cells to data states A, B, C, D, E, F and G, the system will test whether those memory cells have a threshold voltage greater than or equal to VvA, VvB, VvC, VvD, VvE, VvF and VvG, respectively. FIG. 5C also shows Vev, which is an erase verify reference voltage to test whether a memory cell has been properly erased.

In an embodiment that utilizes full sequence programming, memory cells can be programmed from the erased data state Er directly to any of the programmed data states A-G. For example, a population of memory cells to be programmed may first be erased so that all memory cells in the population are in erased data state Er. Then, a programming process is used to program memory cells directly into data states A, B, C, D, E, F, and/or G.

For example, while some memory cells are being programmed from data state Er to data state A, other memory cells are being programmed from data state Er to data state B and/or from data state Er to data state C, and so on. The arrows of FIG. 5C represent the full sequence programming. In some embodiments, data states A-G can overlap, with memory controller 1204 and/or control die 244 relying on error correction to identify the correct data being stored. In some embodiments, rather than using full sequence programming, the system can use multi-pass programming processes known in the art.

In general, during verify operations and read operations, the selected word line is connected to a voltage (one example of a reference signal), a level of which is specified for each read operation (e.g., see read compare voltages/levels VrA, VrB, VrC, VrD, VrE, VrF, and VrG, of FIG. 5C) or verify operation (e.g. see verify target voltages/levels VvA, VvB, VvC, VvD, VvE, VvF, and VvG of FIG. 5C) to determine whether a threshold voltage of the concerned memory cell has reached such level.

After applying the word line voltage, the conduction current of the memory cell is measured to determine whether the memory cell turned ON (conducted current) in response to the voltage applied to the word line. If the conduction current is measured to be greater than a certain value, then it is assumed that the memory cell turned ON and the voltage applied to the word line is greater than the threshold voltage of the memory cell.

If the conduction current is not measured to be greater than the certain value, then it is assumed that the memory cell did not turn ON and the voltage applied to the word line is not greater than the threshold voltage of the memory cell. During a read or verify process, the unselected memory cells are provided with one or more read pass voltages (also referred to as bypass voltages) at their control gates so that these memory cells will operate as pass gates (e.g., conducting current regardless of whether they are programmed or erased).

There are many ways to measure the conduction current of a memory cell during a read or verify operation. In one example, the conduction current of a memory cell is measured by the rate it discharges or charges a dedicated capacitor in a sense amplifier. In another example, the conduction current of the selected memory cell allows (or fails to allow) the NAND string that includes the memory cell to discharge a corresponding bit line. The voltage on the bit line is measured after a period of time to see whether it has been discharged or not. The technology described herein can be used with different methods known in the art for verifying/reading. Other read and verify techniques known in the art can also be used.

FIG. 5D depicts threshold voltage distributions when each memory cell stores four bits of data, which is another example of MLC data. FIG. 5D depicts that there may be some overlap between the threshold voltage distributions (data states) S0-S15. The overlap may occur due to factors such as memory cells losing charge (and hence dropping in threshold voltage).

Program disturb can unintentionally increase the threshold voltage of a memory cell. Likewise, read disturb can unintentionally increase the threshold voltage of a memory cell. Over time, the locations of the threshold voltage distributions may change. Such changes can increase the bit error rate, thereby increasing decoding time or even making decoding impossible. Changing the read reference voltages can help to mitigate such effects. Using ECC during the read process can fix errors and ambiguities.

In some embodiments, the threshold voltage distributions for a population of memory cells storing four bits of data per memory cell do not overlap and are separated from each other. The threshold voltage distributions of FIG. 5D will include read reference voltages and verify reference voltages, as discussed above.

When using four bits per memory cell, the memory can be programmed using the full sequence programming discussed above, or multi-pass programming processes known in the art. Each threshold voltage distribution (data state) of FIG. 5D corresponds to predetermined values for the set of data bits.

The specific relationship between the data programmed into the memory cell and the threshold voltage levels of the cell depends upon the data encoding scheme adopted for the cells. Table 3 provides an example of an encoding scheme for embodiments in which each bit of data of the four bits of data stored in a memory cell are in different logical pages, referred to as a lower page (LP), middle page (MP), an upper page (UP) and top page (TP).

TABLE 3

| | S0 | S1 | S2 | S3 | S4 | S5 | S6 | S7 | S8 | S9 | S10 | S11 | S12 | S13 | S14 | S15 |
|---|---|---|---|---|---|---|---|---|---|---|---|---|---|---|---|---|
| TP | 1 | 1 | 1 | 1 | 1 | 0 | 0 | 0 | 0 | 0 | 1 | 1 | 0 | 0 | 0 | 1 |
| UP | 1 | 1 | 0 | 0 | 0 | 0 | 0 | 0 | 1 | 1 | 1 | 1 | 1 | 1 | 0 | 0 |
| MP | 1 | 1 | 1 | 0 | 0 | 0 | 0 | 1 | 1 | 0 | 0 | 0 | 0 | 1 | 1 | 1 |
| LP | 1 | 0 | 0 | 0 | 1 | 1 | 0 | 0 | 0 | 0 | 0 | 1 | 1 | 1 | 1 | 1 |

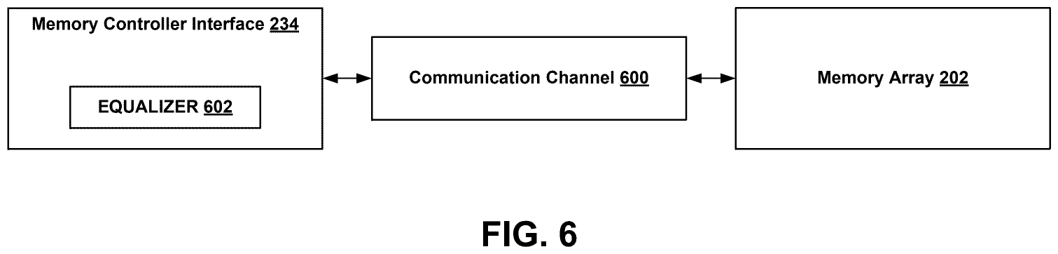

FIG. 6 is a simplified diagram depicting memory controller interface 234 coupled to memory array 202 via a communication channel 600. In embodiments, communication channel 600 may include circuits and data busses through which data are communicated between memory controller interface 234 and memory array 202.

In some embodiments, data received at memory controller interface 234 from memory array 202 may be distorted. For example, data received at memory controller interface 234 from memory array 202 may be affected by intersymbol interference, in which previously received data interferes with subsequently received data.

One technique to suppress or cancel intersymbol interference is to apply an equalization operation to the received data. In an embodiment, memory controller interface 234 includes an equalizer 602 to perform such an equalization operation. In an embodiment, equalizer 602 is a decision feedback equalizer.

In general, a data receiver circuit includes a sense amplifier circuit and a latch circuit. The sense amplifier circuit is used to compare the received data with a reference level, and then the determined result is stored in the latch circuit.

In general, a decision feedback equalizer data receiver circuit includes multiple branch circuits, with each branch circuit including a sense amplifier circuit and a latch circuit. In embodiment, each branch circuit determines a value of a corresponding data sample, and the branch circuits are interconnected in feedback paths such that a branch circuit decides the value of the current data sample based on the decided value of a previous data sample. Each sense amplifier circuit has a sampling phase during which received data are sampled, and a reset phase that resets the sense amplifier prior to the next sampling phase.

Because each branch circuit includes a sense amplifier and latch, feedback delay is a significant factor, which makes designing the decision feedback equalizer difficult. In some embodiments, a “fast feedback” technique is used in decision feedback equalizer circuits to reduce the impact of feedback delay. In some embodiments, such fast feedback decision feedback equalizer circuits use quadrature phase clocks (four separate clock signals offset by 90 degrees from one another). In embodiment, the quadrature phase clocks are required to prevent the feedback signal from changing during the reset phase of the sense amplifier circuit.

However, in many embodiments, memory controller interface 234 is a DDR interface and quadrature phase clocks are not available. Thus, quadrature-phase fast feedback decision feedback equalizer circuits are not a viable option.

Technology is described for fast feedback decision feedback equalizer circuits that do not require quadrature-phase clocks, and that are compatible with DDR non-volatile memory, such as non-volatile memory 106 of FIG. 1, memory die 200 of FIG. 2A and memory die 242 of FIG. 2B, described above.

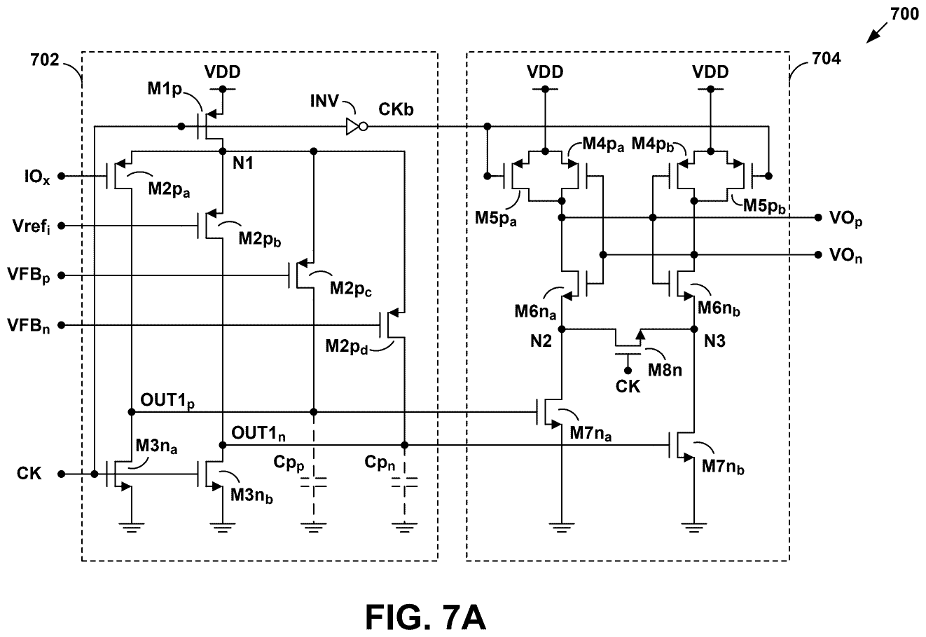

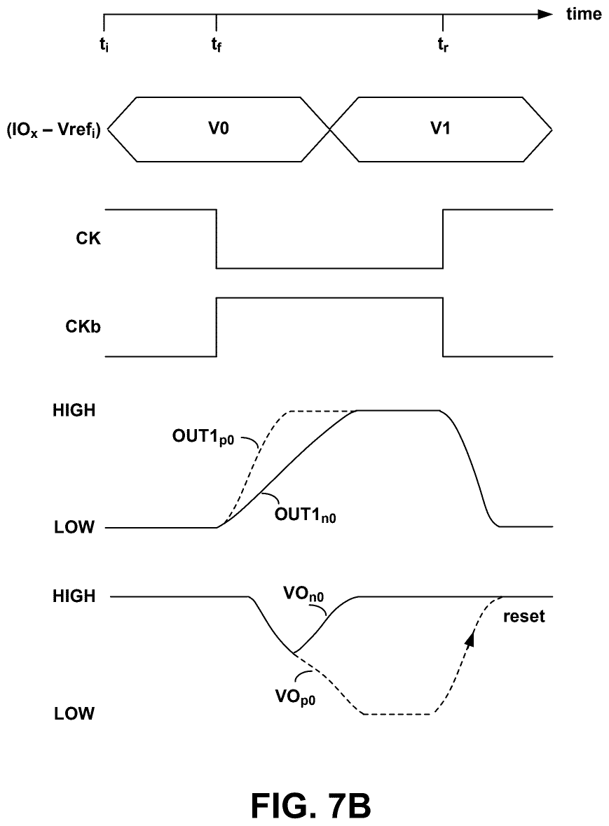

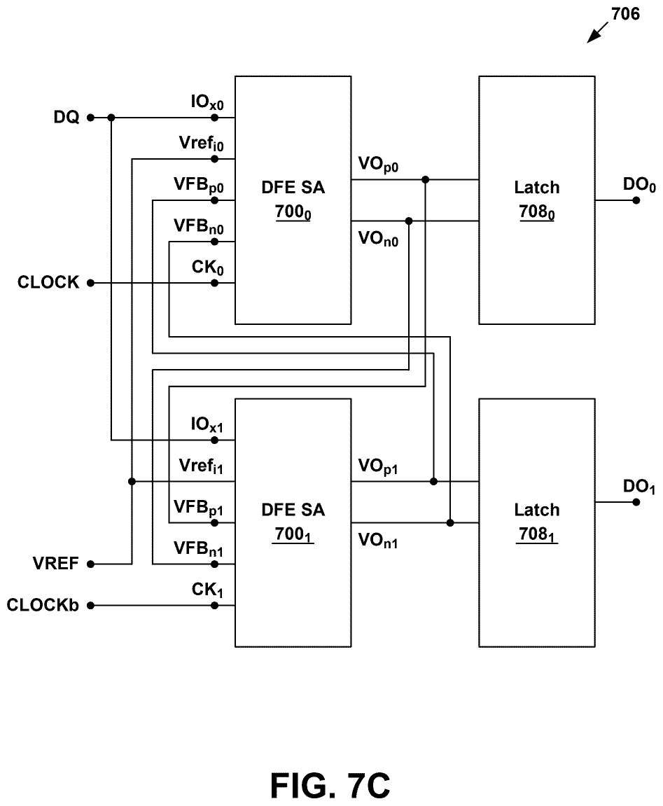

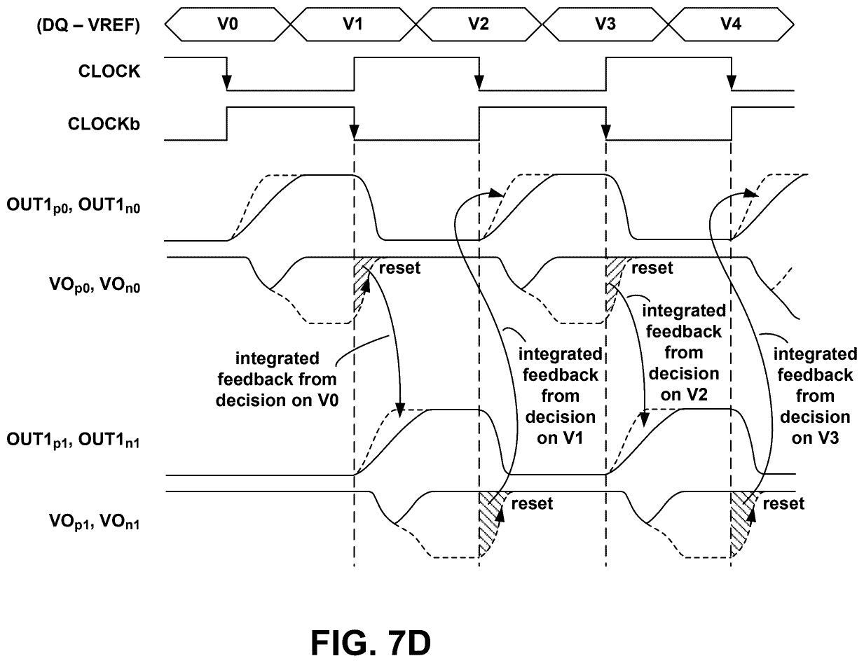

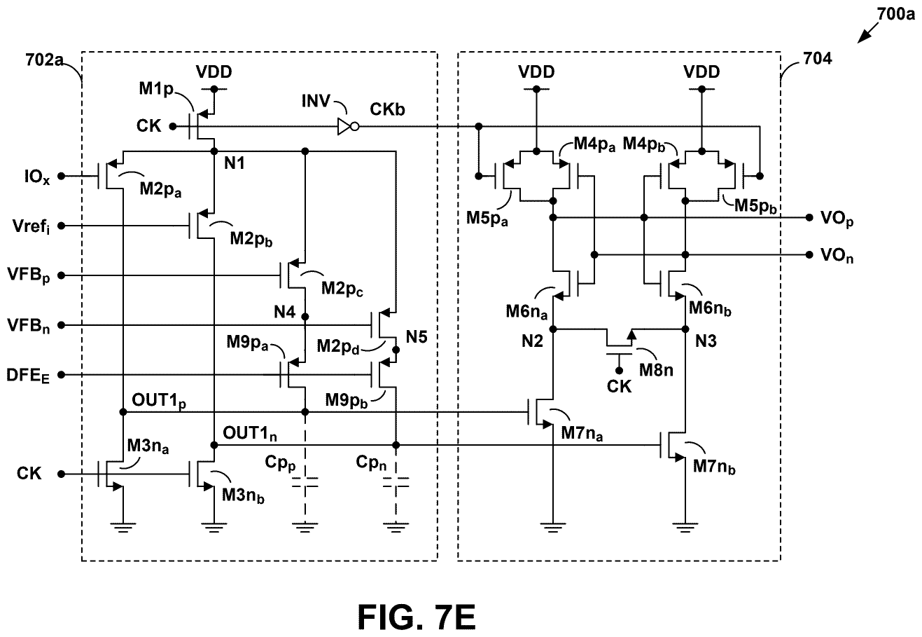

FIG. 7A is a diagram of an embodiment of a decision feedback equalizer (DFE) sense amplifier circuit 700. In an embodiment, equalizer 602 of FIG. 6 includes DFE sense amplifier circuit 700. In an embodiment, DFE sense amplifier circuit 700 includes a first circuit stage 702 and a second circuit stage 704. In an embodiment, first circuit stage 702 is a current amplifier circuit, and thus also will be referred to herein as current amplifier circuit 702. In an embodiment, second circuit stage 704 is a voltage circuit, and thus also will be referred to herein as voltage circuit 704.

In an embodiment, current amplifier circuit 702 includes a first transistor M1p, second transistors M2pₐ, M2p_{b}, M2p_{c} and M2p_{d}, third transistors M3nₐ and M3n_{b}, and an inverter INV. In an embodiment, voltage circuit 704 includes fourth transistors M4pₐ and M4p_{b}, fifth transistors M5pₐ and M5p_{b}, sixth transistors M6nₐ and M6n_{b}, seventh transistors M7nₐ and M7n_{b}, and an eighth transistor m8n.

In an embodiment, current amplifier circuit 702 also includes a first parasitic capacitor Cpₚ and a second parasitic capacitor Cpₙ. Persons of ordinary skill in the art will understand that current amplifier circuit 702 may include additional and/or different circuit elements, and voltage circuit 704 may include additional and/or different circuit elements.

In an embodiment, first transistor M1p has a first terminal (e.g., a drain terminal) coupled to a first node N1, a second terminal (e.g., a gate terminal) coupled to a clock node CK, and a third terminal (e.g., a source terminal) coupled to a first power supply (e.g., VDD). In an embodiment, first transistor M1p is a p-channel transistor.

In an embodiment, second transistor M2pₐ has a first terminal (e.g., a drain terminal) coupled to a first intermediate output node OUT1ₚ, a second terminal (e.g., a gate terminal) coupled to a first input node IOₓ, and a third terminal (e.g., a source terminal) coupled to first node N1. In an embodiment, second transistor M2pₐ is a p-channel transistor.

In an embodiment, second transistor M2p_{b} has a first terminal (e.g., a drain terminal) coupled to a second intermediate output node OUT1ₙ, a second terminal (e.g., a gate terminal) coupled to a second input node Vrefᵢ, and a third terminal (e.g., a source terminal) coupled to first node N1. In an embodiment, second transistor M2p_{b} is a p-channel transistor.

In an embodiment, second transistor M2p_{c} has a first terminal (e.g., a drain terminal) coupled to first intermediate output node OUT1ₚ, a second terminal (e.g., a gate terminal) coupled to a third input node VFBₚ, and a third terminal (e.g., a source terminal) coupled to first node N1. In an embodiment, second transistor M2p_{c} is a p-channel transistor.

In an embodiment, second transistor M2pₐ has a first terminal (e.g., a drain terminal) coupled to second intermediate output node OUT1ₙ, a second terminal (e.g., a gate terminal) coupled to a fourth input node VFBₙ, and a third terminal (e.g., a source terminal) coupled to first node N1. In an embodiment, second transistor M2pₐ is a p-channel transistor.

In an embodiment, third transistor M3nₐ has a first terminal (e.g., a drain terminal) coupled to first intermediate output node OUT1ₚ, a second terminal (e.g., a gate terminal) coupled to clock node CK, and a third terminal (e.g., a source terminal) coupled to a second power supply (e.g., GND). In an embodiment, third transistor M3nₐ is an n-channel transistor.

In an embodiment, third transistor M3n_{b} has a first terminal (e.g., a drain terminal) coupled to second intermediate output node OUT1ₙ, a second terminal (e.g., a gate terminal) coupled to clock node CK, and a third terminal (e.g., a source terminal) coupled to second power supply (e.g., GND). In an embodiment, third transistor M3n_{b} is an n-channel transistor.

In an embodiment, inverter IN has a first terminal coupled to clock node CK and a second terminal coupled to an inverted clock node CKb.

In an embodiment, first parasitic capacitor Cpₚ has a first terminal coupled to first intermediate output node OUT1ₚ, and a second terminal coupled to second power supply GND. In an embodiment, second parasitic capacitor Cpₙ has a first terminal coupled to second intermediate output node OUT1ₙ, and a second terminal coupled to second power supply GND.

In an embodiment, fourth transistor M4pₐ has a first terminal (e.g., a drain terminal) coupled to a first output node VOₚ, a second terminal (e.g., a gate terminal) coupled to a second output node VOₙ, and a third terminal (e.g., a source terminal) coupled to first power supply VDD. In an embodiment, fourth transistor M4pₐ is a p-channel transistor.

In an embodiment, fourth transistor M4p_{b} has a first terminal (e.g., a drain terminal) coupled to second output node VOₙ, a second terminal (e.g., a gate terminal) coupled to first output node VOₚ, and a third terminal (e.g., a source terminal) coupled to first power supply VDD. In an embodiment, fourth transistor M4p_{b} is a p-channel transistor.

In an embodiment, fifth transistor M5pₐ has a first terminal (e.g., a drain terminal) coupled to first output node VOₚ, a second terminal (e.g., a gate terminal) coupled to inverted clock node CKb, and a third terminal (e.g., a source terminal) coupled to first power supply VDD. In an embodiment, fifth transistor M5pₐ is a p-channel transistor.

In an embodiment, fifth transistor M5p_{b} has a first terminal (e.g., a drain terminal) coupled to second output node VOₙ, a second terminal (e.g., a gate terminal) coupled to inverted clock node CKb, and a third terminal (e.g., a source terminal) coupled to first power supply VDD. In an embodiment, fifth transistor M5p_{b} is a p-channel transistor.

In an embodiment, sixth transistor M6nₐ has a first terminal (e.g., a drain terminal) coupled to first output node VOₚ, a second terminal (e.g., a gate terminal) coupled to second output node VOₙ, and a third terminal (e.g., a source terminal) coupled to a second node N2. In an embodiment, sixth transistor M6nₐ is an n-channel transistor.

In an embodiment, sixth transistor M6n_{b} has a first terminal (e.g., a drain terminal) coupled to second output node VOₙ, a second terminal (e.g., a gate terminal) coupled to first output node VOₚ, and a third terminal (e.g., a source terminal) coupled to a third node N3. In an embodiment, sixth transistor M6n_{b} is an n-channel transistor.

In an embodiment, seventh transistor M7nₐ has a first terminal (e.g., a drain terminal) coupled to second node N2, a second terminal (e.g., a gate terminal) coupled to first intermediate output node OUT1ₚ, and a third terminal (e.g., a source terminal) coupled to second power supply GND. In an embodiment, seventh transistor M7nₐ is an n-channel transistor.

In an embodiment, seventh transistor M7n_{b} has a first terminal (e.g., a drain terminal) coupled to third node N3, a second terminal (e.g., a gate terminal) coupled to second intermediate output node OUT1ₙ, and a third terminal (e.g., a source terminal) coupled to second power supply GND. In an embodiment, seventh transistor M7n_{b} is an n-channel transistor.

In an embodiment, eighth transistor M8n has a first terminal (e.g., a drain terminal) coupled to second node N2, a second terminal (e.g., a gate terminal) coupled to clock node CK, and a third terminal (e.g., a source terminal) coupled to third node N3. In an embodiment, eighth transistor M8n is an n-channel transistor.

FIG. 7B depicts various electrical signals of DFE sense amplifier circuit 700 of FIG. 7A. The electrical signals depicted in FIG. 7B represent voltages at the corresponding nodes of DFE sense amplifier circuit 700. To simplify the discussion, the following description will refer to the various electrical signals by the name of the associated node. For example, a clock signal at clock node CK will be referred to as clock signal CK, and a voltage at first intermediate output node OUT1ₚ will be referred to as first intermediate output signal OUT1ₚ.

The signal (IOₓ-Vrefᵢ) represents a voltage difference between an input signal at first input node IOₓ and a reference signal at second input node Verfᵢ. In an embodiment, the input signal IOₓ is a data input signal from a sensed memory cell and reference signal Vrefᵢ is a reference signal used to determine if the data input signal is above or below reference signal Vrefᵢ.

The values V0 and V1 depicted in FIG. 7B thus are either positive or negative, and correspond to data values in input signal IOₓ. For simplicity, values V0 and V1 will be referred to as data values V0 and V1. For example, if a first data value of input signal IOₓ is less than reference signal Vrefᵢ, data value V0 is negative. If a second data value of input signal IOₓ is greater than reference signal Vrefᵢ, data value V1 is positive, and so on.

At time ti, clock signal CK is HIGH (e.g., VDD) and inverted clock signal CKb is LOW (e.g., GROUND). First transistor M1p and second transistors M2pₐ, M2p_{b}, M2b_{c} and M2bₐ are all OFF, third transistors M3nₐ and M3np are ON, which pulls both first intermediate output node OUT1ₚ and second intermediate output node OUT1ₙ LOW. Fifth transistors M5pₐ and M5p_{b} are both ON, which pulls both first output node VOₚ and second output node VOₙ HIGH. Fourth transistors M4pₐ and M4p_{b}, sixth transistors M6nₐ and M6n_{b} and seventh transistors M7nₐ and M7n_{b} are all OFF, and eighth transistor M8n is ON.

On the falling edge of clock signal CK at time tr, third transistors M3nₐ and M3n_{b} turn OFF, effectively removing those transistors from current amplifier circuit 702. First transistor M1p turns ON and begins conducting current and first transistor M1p and second transistors M2pₐ, M2p_{b}, M2p_{c} and M2pₐ function like a current amplifier circuit.

Initially, a first feedback signal VFBₚ and a second feedback signal VFBₙ are both HIGH, and second transistors Mp2_{c} and Mp2ₐ are both OFF. As a result, the current supplied by first transistor M1p is divided into a first current conducted by second transistor M2pₐ and first parasitic capacitor Cpₚ, and a second current conducted by second transistor M2p_{b} and second parasitic capacitor Cpₙ. The first current is integrated by first parasitic capacitor Cpₚ, and the second current is integrated by second parasitic capacitor Cpₙ.

If input signal IOₓ is less than reference signal Vrefᵢ, second transistor M2pₐ will turn ON more that second transistor M2p_{b}, the first current conducted by second transistor M2pₐ and first parasitic capacitor Cpₚ will be greater than the second current conducted by second transistor M2p_{b} and second parasitic capacitor Cpₙ.

As a result, first intermediate output signal OUT1ₚ and second intermediate output signal OUT1ₙ will both rise as charge accumulates on first parasitic capacitor Cpₚ and second parasitic capacitor Cpₙ. However, because second transistor M2pₐ conducts more current than second transistor M2p_{b}, first intermediate output signal OUT1ₚ will rise faster than second intermediate output signal OUT1ₙ.

A difference between first intermediate output signal OUT1ₚ and second intermediate output signal OUT1ₙ corresponds to data value V0. For example, if data value V0 is negative (e.g., input signal IOₓ is less than reference signal Vrefᵢ), the difference between first intermediate output signal OUT1ₚ and second intermediate output signal OUT1ₙ is positive.

In contrast, if data value V0 is positive (e.g., input signal IOₓ is greater than reference signal Vrefᵢ), the difference between first intermediate output signal OUT1ₚ and second intermediate output signal OUT1ₙ is negative. Thus, current amplifier circuit 702 samples data value V0 on the falling edge of clock signal CK.

In voltage circuit 704, first output node VOₚ and second output node VOₙ are initially HIGH, thus fourth transistors M4pₐ and M4p_{b}, fifth transistors M5pₐ and M5p_{b} and eighth transistor M8n are all OFF and sixth transistors M6nₐ and M6nₚ are both ON.

As first intermediate output signal OUT1ₚ and second intermediate output signal OUT1ₙ increase, seventh transistors M7nₐ and M7n_{b} begin turning ON, pulling second node N2, third node N3, first output node VOₚ and second output node VOₙ LOW. However, first intermediate output signal OUT1ₚ increases at a faster rate than second intermediate output signal OUT1ₙ, and thus first output signal VOₚ is pulled LOW faster than second output signal VOₙ.

Fourth transistors M4pₐ and M4p_{b} and sixth transistors M6nₐ and Mon form a cross-coupled pair. Thus, as first output signal VOₚ is pulled LOW, fourth transistor M4p_{b} turns ON and pulls second output signal VOₙ back HIGH. This is depicted in FIG. 7B, in which first output signal VOₚ second output signal VOₙ both begin going LOW, but second output signal VOₙ returns HIGH.

Thus, a difference between first output signal VOₚ and second output signal VOₙ corresponds to data value V0 sampled on the falling edge of clock signal CK. For example, if data value V0 is negative (e.g., data input signal IOₓ is less than reference signal Vrefᵢ), the difference between first output signal VOₚ and second output signal VOₙ is negative. In contrast, if data value V0 is positive (e.g., data input signal IOₓ is greater than reference signal Vrefᵢ), the difference between first output signal VOₚ and second output signal VOₙ is positive.

In an embodiment, a difference between first output signal VOₚ and second output signal VOₙ corresponds to a decision of a value of the data input signal IOₓ. For example, a negative difference between first output signal VOₚ and second output signal VOₙ corresponds to decision that on the falling edge of clock signal CK, data input signal IOₓ had a value of LOW (e.g., “0”). In contrast, a positive difference between first output signal VOₚ and second output signal VOₙ corresponds to decision that on the falling edge of clock signal CK, data input signal IOₓ had a value of HIGH (e.g., “1”).

Referring again to FIG. 7B, on the rising edge of clock signal CK at time tr, first transistor M1p, second transistors M2pₐ, M2p_{b}, M2b_{c} and M2pₐ all turn OFF, and third transistors M3nₐ and M3n_{b} turn ON, discharging first parasitic capacitor Cpₚ and second parasitic capacitor Cpₙ, and pulling first intermediate output signal OUT1ₚ and second intermediate output signal OUT1ₙ both LOW.

Inverted clock signal CKb goes LOW, turning ON fifth transistors M5pₐ and M5p_{b}, pulling first output signal VOₚ and second output signal VOₙ HIGH, which turns OFF fourth transistors M4pₐ and M4p_{b}. First intermediate output signal OUT1ₚ and second intermediate output signal OUT1ₙ going LOW turns OFF seventh transistors M7nₐ and M7n_{b}. Eighth transistor M8n turns ON, coupling second node N2 and third node N3 together, which are pulled HIGH.

Thus, on the rising edge of clock signal CK DFE sense amplifier circuit 700 of FIG. 7A resets to initial conditions: first intermediate output signal OUT1ₚ and second intermediate output signal OUT1ₙ are both LOW, and first output signal VOₚ and second output signal VOₙ are both HIGH.

The description above assumed that first feedback signal VFBₚ and a second feedback signal VFBₙ are both HIGH, and second transistors Mp2_{c} and Mp2ₐ are both OFF. However, as described in more detail below, first feedback signal VFBₚ and second feedback signal VFBₙ may be coupled to a first output node VOₚ and second output node VOₙ, respectively, of another DFE sense amplifier circuit 700 that is configured to sample a previous data value Vx sampled on the falling edge of inverted clock signal CKb.

In such a scenario, the current supplied by first transistor M1p is divided into a first current conducted by second transistor M2pₐ and first parasitic capacitor Cpₚ, a second current conducted by second transistor M2p_{b} and second parasitic capacitor Cpₙ, a third current conducted by second transistor M2p_{c} and first parasitic capacitor Cpₚ, and a fourth current conducted by second transistor M2pₐ and second parasitic capacitor Cpₙ. The first current and third current are integrated by first parasitic capacitor Cpₚ, and the second current and the fourth current are integrated by second parasitic capacitor Cpₙ.

FIG. 7C is a simplified block diagram of an embodiment of a DFE system 706 that includes DFE sense amplifier circuits 700 of FIG. 7A. In an embodiment, equalizer 602 of FIG. 6 includes DFE system 706. In particular, DFE system 706 includes a first DFE sense amplifier circuit 7000, a second DFE sense amplifier circuit 7001, a first latch circuit 7080 and a second latch circuit 7081. In an embodiment, each of first DFE sense amplifier circuit 7000, and second DFE sense amplifier circuit 7001 is an instance of DFE sense amplifier circuit 700 of FIG. 7A.

First DFE sense amplifier circuit 7000 includes a first input node IOₓ₀, a second input node Vrefᵢ₀, a third input node VFBp₀, a fourth input node VFBₙ₀, a clock node CK₀, a first output node VOₚ₀ and a second output node Voₙ₀.

Second DFE sense amplifier circuit 7001 includes a first input node IOₓ₁, a second input node Vrefᵢ₁, a third input node VFBp₁, a fourth input node VFBₙ₁, a clock node CK₁, a first output node VOₚ₁ and a second output node Voₙ₁.

First latch circuit 7080 includes a first input terminal coupled to first output node VOₚ₀ of first DFE sense amplifier circuit 7000, a second input terminal coupled to second output node Voₙ₀ of first DFE sense amplifier circuit 7000, and a first latch output node DO₀.

Second latch circuit 7081 includes a first input terminal coupled to first output node VOₚ₁ of second DFE sense amplifier circuit 7001, a second input terminal coupled to second output node Voₙ₁ of second DFE sense amplifier circuit 7001, and a second latch output node DO₁.

First input node IOₓ₀ of first DFE sense amplifier circuit 7000 and first input node IOₓ₁ of second DFE sense amplifier circuit 7001 are coupled to a data input signal DQ. Second input node Vrefᵢ₀ of first DFE sense amplifier circuit 7000 and second input node Vrefᵢ₁ of second DFE sense amplifier circuit 7001 are coupled to a reference signal VREF.

Third input node VFBp₀ of first DFE sense amplifier circuit 7000 is coupled to first output node VOₚ₁ of second DFE sense amplifier circuit 7001, and fourth input node VFBₙ₀ of first DFE sense amplifier circuit 7000 is coupled to second output node VOₙ₁ of second DFE sense amplifier circuit 7001.

Third input node VFBp₁ of second DFE sense amplifier circuit 7001 is coupled to first output node VOₚ₀ of first DFE sense amplifier circuit 7000, and fourth input node VFBₙ₁ of second DFE sense amplifier circuit 7001 is coupled to second output node VOₙ₀ of first DFE sense amplifier circuit 7000.

Clock node CK₀ of first DFE sense amplifier circuit 7000 is coupled to a clock signal CLOCK, and clock node CK₁ of second DFE sense amplifier circuit 7001 is coupled to a clock signal CLOCKb. In an embodiment, clock signal CLOCKb is an inverted version of clock signal CLOCK.

FIG. 7D is a diagram that depicts various electrical signals of DFE system 706 of FIG. 7C. The electrical signals depicted in FIG. 7D represent voltages at the corresponding nodes of DFE system 706. In addition, FIG. 7D also depicts first intermediate output signal OUT1ₚ₀ and second intermediate output signal OUT1ₙ₀ of first DFE sense amplifier circuit 7000, and first intermediate output signal OUT1ₚ₁ and second intermediate output signal OUT1ₙ₁ of second DFE sense amplifier circuit 7001.

The signal (DQ-VREF) represents a voltage difference between data input signal DQ and reference signal VREF. In an embodiment, data input signal DQ is a data input signal from a sensed memory cell and reference signal VREF is a reference signal used to determine if data input signal DQ is above or below reference signal VREF.

The values V0 and V1 depicted in FIG. 7D thus are either positive or negative, and correspond to data values in data input signal DQ. For simplicity, values V0 and V1 will be referred to as data values V0 and V1. For example, if a first data value of data input signal DQ is less than reference signal VREF, data value V0 is negative. If a second data value of data input signal DQ is greater than reference signal VREF, data value V1 is positive, and so on.

On the first falling edge of clock signal CLOCK current amplifier circuit 702 of first DFE sense amplifier circuit 7000 samples data value V0. A difference between first intermediate output signal OUT1ₚ₀ and second intermediate output signal OUT1ₙ₀ of first DFE sense amplifier circuit 7000 corresponds to data value V0. For example, if data value V0 is negative (e.g., data input signal DQ is less than reference signal VREF), the difference between first intermediate output signal OUT1ₚ₀ and second intermediate output signal OUT1ₙ₀ of first DFE sense amplifier circuit 7000 is positive.

In an embodiment, a difference between first output signal VOₚ₀ and second output signal VOₙ₀ of first DFE sense amplifier circuit 7000 corresponds to data value V0 sampled on the falling edge of clock signal CLOCK. For example, if data value V0 is negative (e.g., data input signal DQ is less than reference signal VREF), the difference between first output signal VOₚ₀ and second output signal VOₙ₀ of first DFE sense amplifier circuit 7000 is negative. In an embodiment, a difference between first output signal VOₚ₀ and second output signal VOₙ₀ corresponds to a decision of a value of data value V0.

On the first falling edge of inverted clock signal CLOCKb current amplifier circuit 702 of second DFE sense amplifier circuit 7001 samples data value V1. In addition, first output signal VOₚ₀ and second output signal VOₙ₀ of first DFE sense amplifier circuit 7000 are fed back to third input node VFBp₁ and fourth input node VFBₙ₁, respectively, respectively, of second DFE sense amplifier circuit 7001. These feedback signals are integrated on first parasitic capacitor Cpₚ and second parasitic capacitor Cpₙ, respectively, of current amplifier circuit 702 of second DFE sense amplifier circuit 7001.

As a result, a difference between first intermediate output signal OUT1ₚ₁ and second intermediate output signal OUT1ₙ₁ of second DFE sense amplifier circuit 7001 corresponds to data value V1 minus the fed back decision on data value V0 from first DFE sense amplifier circuit 7000.

This is depicted in FIG. 7D in which the shaded area between the curves for first output signal VOₚ₀ and second output signal VOₙ₀ of first DFE sense amplifier circuit 7000 represents the charge integrated on first parasitic capacitor Cpₚ and second parasitic capacitor Cpₙ of current amplifier circuit 702 of second DFE sense amplifier circuit 7001. In this regard, without wanting to be bound by any particular theory it is believed that DFE system 706 may cancel intersymbol interference from data value V0 on data value V1.

In an embodiment, a difference between first output signal VOₚ₁ and second output signal VOₙ₁ of second DFE sense amplifier circuit 7001 corresponds to data value V1 sampled on the falling edge of inverted clock signal CLOCKb, minus the decision from data value V0. In an embodiment, a difference between first output signal VOₚ₁ and second output signal VOₙ₁ corresponds to a decision of a value of data value V1.

This process then repeats. Thus, on the second falling edge of clock signal CLOCK, current amplifier circuit 702 of first DFE sense amplifier circuit 7000 samples data value V2. In addition, first output signal VOₚ₁ and second output signal VOₙ₁ of second DFE sense amplifier circuit 7001 are fed back to third input node VFBp₀ and fourth input node VFBₙ₀, respectively, respectively, of first DFE sense amplifier circuit 7000. These feedback signals are integrated on first parasitic capacitor Cpₚ and second parasitic capacitor Cpₙ, respectively, of current amplifier circuit 702 of first DFE sense amplifier circuit 7000.

As a result, a difference between first intermediate output signal OUT1ₚ₀ and second intermediate output signal OUT1ₙ₀ of first DFE sense amplifier circuit 7000 corresponds to data value V2 minus the fed back decision on data value V1 from second DFE sense amplifier circuit 7001.

This is depicted in FIG. 7D in which the shaded area between the curves for first output signal VOₚ₁ and second output signal VOₙ₁ of second DFE sense amplifier circuit 7001 represents the charge integrated on first parasitic capacitor Cpₚ and second parasitic capacitor Cpₙ of current amplifier circuit 702 of first DFE sense amplifier circuit 7000. In this regard, without wanting to be bound by any particular theory it is believed that DFE system 706 may cancel intersymbol interference from data value V1 on data value V2.

In an embodiment, a difference between first output signal VOₚ₀ and second output signal VOₙ₀ of first DFE sense amplifier circuit 7000 corresponds to data value V2 sampled on the falling edge of clock signal CLOCK, minus the decision from data value V1. In an embodiment, a difference between first output signal VOₚ₀ and second output signal VOₙ₀ corresponds to a decision of a value of data value V2.

In an embodiment, this process continues with the determination of each data value being based on the sampled data value minus the decision from the immediately preceding data value.

In some instances, for example, when channel characteristics are very good such that intersymbol interference is negligible, it may be desirable to turn OFF the DFE feedback in DFE sense amplifier circuits 700. In other words, in such circumstances a decision result may be better without including the feedback from the decision on the immediately preceding data value.

FIG. 7E is a diagram of another embodiment of a DFE sense amplifier circuit 700a. In an embodiment, equalizer 602 of FIG. 6 includes DFE sense amplifier circuit 700a. DFE sense amplifier circuit 700a is identical to DFE sense amplifier circuit 700 of FIG. 7A, but includes a first circuit 702a which includes ninth transistors M9pₐ and M9p_{b}.

In an embodiment, ninth transistor M9pₐ has a first terminal (e.g., a drain terminal) coupled to first intermediate output node OUT1ₚ, a second terminal (e.g., a gate terminal) coupled to a fifth input node DFE_{E}, and a third terminal (e.g., a source terminal) coupled to a fourth node N4. In an embodiment, ninth transistor M2pₐ is a p-channel transistor.

In an embodiment, ninth transistor M9p_{b} has a first terminal (e.g., a drain terminal) coupled to second intermediate output node OUT1ₙ, a second terminal (e.g., a gate terminal) coupled to fifth input node DFE_{E}, and a third terminal (e.g., a source terminal) coupled to a fifth node N5. In an embodiment, ninth transistor M2p_{b} is a p-channel transistor.

In an embodiment, second transistor M2p_{c} has a first terminal (e.g., a drain terminal) coupled to fourth node N4, a second terminal (e.g., a gate terminal) coupled to a third input node VFBₚ, and a third terminal (e.g., a source terminal) coupled to first node N1. In an embodiment, second transistor M2pₐ has a first terminal (e.g., a drain terminal) coupled to fifth node N5, a second terminal (e.g., a gate terminal) coupled to a fourth input node VFBₙ, and a third terminal (e.g., a source terminal) coupled to first node N1.

In an embodiment, a decision feedback enable signal DFE_{E} coupled to fifth input node DFE_{E} effectively enables or disables feedback from signals coupled to third input node VFBₚ and fourth input node VFBₙ. In an embodiment, if decision feedback enable signal DFE_{E} has a first value (e.g., LOW), ninth transistors M9pₐ and M9p_{b} are turned ON, and feedback is enabled. That is, feedback signals coupled to third input node VFBₚ and fourth input node VFBₙ are used to integrate current on first parasitic capacitor Cpₚ and second parasitic capacitor Cpₙ.

In an embodiment, if decision feedback enable signal DFE_{E} has a second value (e.g., HIGH), ninth transistors M9pₐ and M9p_{b} are turned OFF, and feedback is disabled. That is, feedback signals coupled to third input node VFBₚ and fourth input node VFBₙ are not used to integrate current on first parasitic capacitor Cpₚ and second parasitic capacitor Cpₙ.

Thus, the decision feedback enable signal DFE_{E} signal can be used to selectively apply decision feedback equalization in DFE sense amplifier circuit 700a. For example, referring again to FIG. 6, communication channel 600 is disposed between a non-volatile memory array 202 and memory controller interface 234. In an embodiment, equalizer 602 of memory controller interface 234 includes a first decision feedback equalizer sense amplifier circuit 700a of FIG. 7E.

In some instances, communication channel 600 may have very bad distortion characteristics. In such instances, system performance may be better by using decision feedback equalization. Accordingly, decision feedback enable signal DFE_{E} may be set to first value (e.g., LOW) to enable the feedback circuit that includes ninth transistors M9pₐ and M9p_{b}.

In other instances, communication channel 600 has excellent characteristics with very low to no distortion. In such an instance, system performance may be better without using decision feedback equalization. Accordingly, decision feedback enable signal DFE_{E} may be set to second value (e.g., HIGH) to disable the feedback circuit that includes ninth transistors M9pₐ and M9p_{b}.

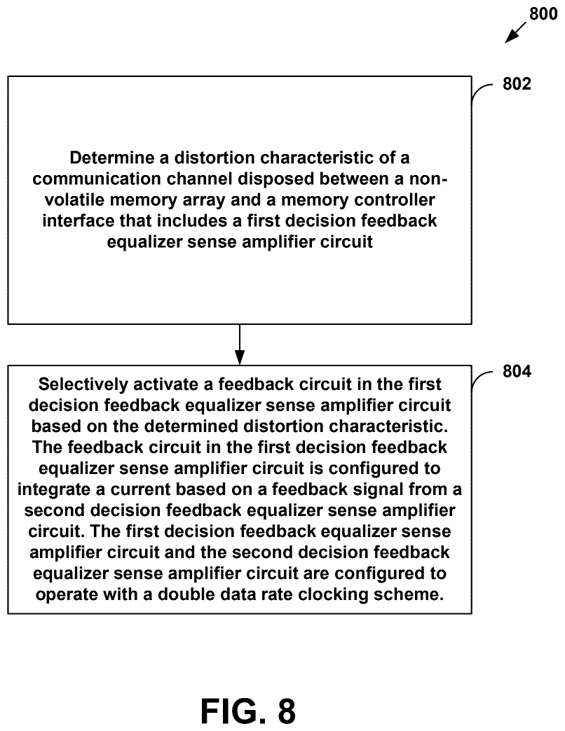

FIG. 8 is a flowchart of a method 800 for use with DFE sense amplifier circuit 700a of FIG. 7E.

At step 802, a distortion characteristic of a communication channel that is disposed between a non-volatile memory array and a memory controller interface that includes a first decision feedback equalizer sense amplifier circuit is determined.

At step 802, a feedback circuit in the first decision feedback equalizer sense amplifier circuit is selectively activated based on the determined distortion characteristic. For example, as described above, a value of decision feedback enable signal DFE_{E} may be set to either enable or disable the feedback circuit that includes ninth transistors M9pₐ and M9p_{b} in DFE sense amplifier circuit 700a of FIG. 7E.

In an embodiment, an apparatus is provided that includes a first circuit stage that includes a current amplifier circuit configured to receive a data input signal and a feedback signal, and a second circuit stage including a voltage circuit coupled to the first circuit stage. The first circuit stage is configured to integrate a current based on the data input signal and the feedback signal. The second circuit stage is configured to provide an output signal corresponding to a decision of a value of the data input signal. The apparatus is configured to operate with a double data rate clocking scheme.

In an embodiment, a system is provided that includes a first decision feedback equalizer sense amplifier circuit and a second decision feedback equalizer sense amplifier circuit. The first decision feedback equalizer sense amplifier circuit includes a first input node coupled to a data input signal, a second input node coupled to a reference signal, a third input node, a fourth input node, a first output node and a second output node. The second decision feedback equalizer sense amplifier circuit includes a first input node coupled to the data input signal, a second input node coupled to the reference signal, a third input node coupled to the first output node of the first decision feedback equalizer sense amplifier circuit, a fourth input node coupled to the second output node of the first decision feedback equalizer sense amplifier circuit, a first output node coupled to the third input node of the first decision feedback equalizer sense amplifier circuit and a second output node coupled to the fourth input node of the first decision feedback equalizer sense amplifier circuit. The first decision feedback equalizer sense amplifier circuit and the second decision feedback equalizer sense amplifier circuit are configured to operate with a double data rate clocking scheme.

In an embodiment, an method is provided that includes determining a distortion characteristic of a communication channel disposed between a non-volatile memory array and a memory controller interface that includes a first decision feedback equalizer sense amplifier circuit, and selectively activating a feedback circuit in the first decision feedback equalizer sense amplifier circuit based on the determined distortion characteristic. The feedback circuit in the first decision feedback equalizer sense amplifier circuit is configured to integrate a current based on a feedback signal from a second decision feedback equalizer sense amplifier circuit. The first decision feedback equalizer sense amplifier circuit and the second decision feedback equalizer sense amplifier circuit are configured to operate with a double data rate clocking scheme.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more others parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

1. An apparatus comprising:
a first circuit stage comprising a current amplifier circuit configured to receive a data input signal and a feedback signal; and
a second circuit stage comprising a voltage circuit coupled to the first circuit stage,
wherein:
the first circuit stage is configured to integrate a current based on the data input signal and the feedback signal;
the second circuit stage is configured to provide an output signal corresponding to a decision of a value of the data input signal; and
the apparatus is configured to operate with a double data rate clocking scheme.

2. The apparatus of claim 1, wherein:
the first circuit stage comprises a first input node and a second input node; and
the first circuit stage is further configured to integrate a first current and a second current based on a voltage difference between the first input node and the second input node.

3. The apparatus of claim 1, wherein the first circuit stage is further configured to:
receive a reference signal; and
integrate a first current and a second current based on a difference between the data input signal and the reference signal.

4. The apparatus of claim 1, wherein:
the first circuit stage comprises a first input node and a second input node; and
the first circuit stage is further configured to integrate a first current on a first parasitic capacitor based on a voltage at the first input node and integrate a second current on a second parasitic capacitor based on a voltage at the second input node.

5. The apparatus of claim 1, wherein:
the first circuit stage comprises a first input node, a second input node, a third input node and a fourth input node; and
the first circuit stage is further configured to integrate a first current on a first parasitic capacitor based on a voltage at the first input node, integrate a second current on a second parasitic capacitor based on a voltage at the second input node, integrate a third current on the first parasitic capacitor based on a voltage at the third input node, and integrate a fourth current on the second parasitic capacitor based on a voltage at the fourth input node.

6. The apparatus of claim 1, wherein:
the first circuit stage is further configured to generate a first intermediate output signal and a second intermediate output signal; and
the second circuit stage is further configured to provide the output signal based on a difference between the first intermediate output signal and the second intermediate output signal.

7. The apparatus of claim 1, wherein:
the first circuit stage is further configured to generate a first intermediate output signal and a second intermediate output signal; and
the second circuit stage is further configured to provide a first output signal and a second output signal based on the first intermediate output signal and the second intermediate output signal.

8. The apparatus of claim 1, wherein:
the first circuit stage is further configured to sample the data input signal based on an edge of a first clock signal; and
the second circuit stage is further configured to provided the output signal corresponding to a decision of a value of the sampled data input signal.

9. The apparatus of claim 8, wherein the first circuit stage and the second circuit stage are configured to reset based on an edge of a second clock signal.

10. The apparatus of claim 9, wherein the second clock signal is an inverted version of the first clock signal.

11. The apparatus of claim 1, comprising a decision feedback equalizer sense amplifier circuit.

12. The apparatus of claim 1, further comprising:
a non-volatile memory array coupled to the first circuit stage,
wherein data read from the non-volatile memory array comprises the data input signal.

13. The apparatus of claim 1, wherein the feedback signal corresponds to a decision of a value of previous data input signal.

14. A system comprising:
a first decision feedback equalizer sense amplifier circuit comprising a first input node coupled to a data input signal, a second input node coupled to a reference signal, a third input node, a fourth input node, a first output node and a second output node; and
a second decision feedback equalizer sense amplifier circuit comprising a first input node coupled to the data input signal, a second input node coupled to the reference signal, a third input node coupled to the first output node of the first decision feedback equalizer sense amplifier circuit, a fourth input node coupled to the second output node of the first decision feedback equalizer sense amplifier circuit, a first output node coupled to the third input node of the first decision feedback equalizer sense amplifier circuit and a second output node coupled to the fourth input node of the first decision feedback equalizer sense amplifier circuit,
wherein the first decision feedback equalizer sense amplifier circuit and the second decision feedback equalizer sense amplifier circuit are configured to operate with a double data rate clocking scheme.

15. The system of claim 14, wherein the first decision feedback equalizer sense amplifier circuit and the second decision feedback equalizer sense amplifier circuit each include a current amplifier circuit and a voltage circuit coupled to the current amplifier circuit.

16. The system of claim 14, wherein the first decision feedback equalizer sense amplifier circuit comprises a first circuit stage configured to integrate a current based on the data input signal, a signal at the first output node of the second decision feedback equalizer sense amplifier circuit, and a signal at the second output node of the second decision feedback equalizer sense amplifier circuit.

17. The system of claim 14, wherein the second decision feedback equalizer sense amplifier circuit comprises a first circuit stage configured to integrate a current based on the data input signal, a signal at the first output node of the first decision feedback equalizer sense amplifier circuit, and a signal at the second output node of the first decision feedback equalizer sense amplifier circuit.

18. The system of claim 14, further comprising:
a first clock signal coupled to the first decision feedback equalizer sense amplifier circuit; and
a second clock signal coupled to the first decision feedback equalizer sense amplifier circuit,
wherein the second clock signal is an inverted version of the first clock signal.

19. The system of claim 14, further comprising:
a non-volatile memory array coupled to the first decision feedback equalizer sense amplifier circuit and the second decision feedback equalizer sense amplifier circuit,
wherein data read from the non-volatile memory array comprises the data input signal.

20. A method comprising:
determining a distortion characteristic of a communication channel disposed between a non-volatile memory array and a memory controller interface that comprises a first decision feedback equalizer sense amplifier circuit; and
selectively activating a feedback circuit in the first decision feedback equalizer sense amplifier circuit based on the determined distortion characteristic,
wherein:
the feedback circuit in the first decision feedback equalizer sense amplifier circuit is configured to integrate a current based on a feedback signal from a second decision feedback equalizer sense amplifier circuit;
the first decision feedback equalizer sense amplifier circuit and the second decision feedback equalizer sense amplifier circuit are configured to operate with a double data rate clocking scheme.
